(19) United States
(12) Patent Application Publication
(10) Pub. No.: US 2014/0144500 A1
(43) Pub. Date: May 29, 2014

(54) SEMICONDUCTOR INKS FILMS, COATED SUBSTRATES AND METHODS OF PREPARATION

(71) Applicants: Yanyan Cao, Wilmington, DE (US); John W. Catron, JR., Smyrna, DE (US); Lynda Kaye Johnson, Wilmington, DE (US); Meijun Lu, Hockessin, DE (US); Daniela Rodica Radu, Hockessin, DE (US); Jonathan V. Caspar, Wilmington, DE (US); Irina Malajovich, Swarthmore, PA (US); H. David Rosenfeld, Drumore, PA (US)

(72) Inventors: Yanyan Cao, Wilmington, DE (US); John W. Catron, JR., Smyrna, DE (US); Lynda Kaye Johnson, Wilmington, DE (US); Meijun Lu, Hockessin, DE (US); Daniela Rodica Radu, Hockessin, DE (US); Jonathan V. Caspar, Wilmington, DE (US); Irina Malajovich, Swarthmore, PA (US); H. David Rosenfeld, Drumore, PA (US)

(73) Assignee: E I DU PONT DE NEMOURS AND COMPANY, Wilmington, DE (US)

(21) Appl. No.: 13/885,286

(22) PCT Filed: Nov. 20, 2011
(86) PCT No.: PCT/US11/61568

§ 371 Date: Jun. 6, 2013

Related U.S. Application Data
(60) Provisional application No. 61/416,024, filed on Nov. 22, 2010.
(60) Provisional application No. 61/416,029, filed on Nov. 22, 2010.

(51) Int. Cl. H01L 31/032; H01L 31/18

(52) U.S. Cl. CPC H01L 31/0322; H01L 31/18
USPC 136/256; 257/613; 438/478; 252/519.21

(57) ABSTRACT

This invention provides compositions useful for preparing films of CZTS and its selenium analogues on a coated substrate. This invention also provides processes for preparing films and coated substrates comprising CZTS/Se microparticles embedded in an inorganic matrix. This invention also provides processes for preparing photovoltaic cells comprising films of CZTS and its selenium analogues.

This application claims the benefit of U.S. Provisional Patent Application No. 61/416,024, filed Nov. 22, 2010 and U.S. Provisional Patent Application No. 61/416,029, filed Nov. 22, 2010 which are herein incorporated by reference.

### FIELD OF THE INVENTION

This invention provides processes and compositions useful for preparing films of CZTS and its selenium analogues on a substrate. This invention also provides processes for preparing photovoltaic cells comprising films of CZTS and its selenium analogues. This invention also relates to a semiconductor layer comprising CZTS/Se microparticles embedded in an inorganic matrix as well as processes for preparing such a semiconductor layer. This invention also relates to photovoltaic cells comprising films of CZTS and its selenium analogues and to processes for preparing these cells.

### BACKGROUND

Thin-film photovoltaic cells typically use semiconductors such as CdTe or copper indium gallium sulfide/selenide (CIGS) as an energy absorber material. Due to the toxicity of cadmium and the limited availability of indium, alternatives are sought. Copper zinc tin sulfide (Cu₂ZnSnS₄ or “CZTS”) possesses a band gap energy of about 1.5 eV and a large absorption coefficient (approx. 10⁴ cm⁻¹), making it a promising CIGS replacement.

The most common approach to fabricating CZTS thin films is to deposit elemental or binary precursors, such as Cu, Zn, Sn, ZnS, and SnS, using a vacuum technique, which is then followed by the chalcogenization of the precursors. The resulting films are continuous deposits which conform to the substrate. However, typical vacuum techniques require complicated equipment and are therefore intrinsically expensive processes.

Low-cost routes to CZTS are available, but have deficiencies. For example, electrochemical deposition to form CZTS is an inexpensive process, but compositional non-uniformity and/or the presence of secondary phases prevents this method from generating high-quality CZTS thin-films. CZTS thin-films can also be made by the spray pyrolysis of a solution containing metal salts, typically CuCl, ZnCl₂, and SnCl₄, using thiourea as the sulfur source. This method tends to yield films of poor morphology, density and grain size. CZTS films formed from oxyhydrate precursors deposited by the sol-gel method also have poor morphology and require an H₂S atmosphere for annealing. Photochemical deposition has also been shown to generate p-type CZTS thin films. However, the composition of the product is not well-controlled, and it is difficult to avoid the formation of impurities such as hydroxides. The synthesis of CZTS films from CZTS nanoparticles, which incorporate high-boiling amines as capping agents, has also been disclosed. The presence of capping agents in the nanoparticle layer can contaminate and lower the density of the annealed CZTS film. A hybrid solution-particle approach to CZTS involving the preparation of a hydrazine-based slurry comprising dissolved Cu—Sn chalcogenides (S or S—Se), Zn-chalcogenide particles, and excess chalcogen has been reported. However, hydrazine is a highly reactive and potentially explosive solvent that is described in the Merck Index as a “violent poison.”

Mixtures of milled copper, zinc, and tin particles have been used to form CZTS in a complex, multi-step process. This process involves pressing the particle mixture, heating the pressed particles in a vacuum in a sealed tube to form an alloy, melt-spinning to form an alloy strip, mixing the alloy strip with sulfur powder and ball-milling to form a precursor mixture. This mixture can be coated and then annealed under sulfur vapor to form a film of CZTS.

Hence, there still exists a need for simple, low-cost, scalable materials and processes with a low number of operations that provide high-quality, crystalline CZTS films with tunable composition and morphology. There also exists a need for low-temperature, atmospheric-pressure routes to these materials using solvents and reagents with relatively low toxicity.

### SUMMARY

One aspect of this invention is an ink comprising:

a) a molecular precursor to CZTS/Se, comprising:
i) a copper source selected from the group consisting of copper complexes of N-, O-, C-, S-, and Se-based organic ligands, copper sulfides, copper selenides, and mixtures thereof;
ii) a tin source selected from the group consisting of tin complexes of N-, O-, C-, S-, and Se-based organic ligands, tin hydrides, tin sulfides, tin selenides, and mixtures thereof;
iii) a zinc source selected from the group consisting of zinc complexes of N-, O-, C-, S-, and Se-based organic ligands, zinc sulfides, zinc selenides, and mixtures thereof; and
iv) a vehicle, comprising a liquid chalcogen compound, a liquid tin source, a solvent, or a mixture thereof; and
   b) a plurality of particles selected from the group consisting of: CZTS/Se particles; elemental Cu-, elemental Zn- or elemental Sn-containing particles; binary or ternary Cu-, Zn- or Sn-containing chalcogenide particles; and mixtures thereof.

Another aspect of this invention is a process comprising disposing an ink onto a substrate to form a coated substrate, wherein the ink comprises:

a) a molecular precursor to CZTS/Se, comprising:
i) a copper source selected from the group consisting of copper complexes of N-, O-, C-, S-, and Se-based organic ligands, copper sulfides, copper selenides, and mixtures thereof;
ii) a tin source selected from the group consisting of tin complexes of N-, O-, C-, S-, and Se-based organic ligands, tin hydrides, tin sulfides, tin selenides, and mixtures thereof;
iii) a zinc source selected from the group consisting of zinc complexes of N-, O-, C-, S-, and Se-based organic ligands, zinc sulfides, zinc selenides, and mixtures thereof; and
iv) a vehicle, comprising a liquid chalcogen compound, a liquid tin source, a solvent, or a mixture thereof; and
   b) a plurality of particles selected from the group consisting of: CZTS/Se particles; elemental Cu-, elemental Zn- or elemental Sn-containing particles; binary or ternary Cu-, Zn- or Sn-containing chalcogenide particles; and mixtures thereof.

Another aspect of this invention is a coated substrate comprising:

A) a substrate; and
B) at least one layer disposed on the substrate comprising:
1) a molecular precursor to CZTS/Se, comprising:
   a) a copper source selected from the group consisting of copper complexes of N-, O-, C-, S-, and Se-based organic ligands, copper sulfides, copper selenides, and mixtures thereof;
   b) a tin source selected from the group consisting of tin complexes of N-, O-, C-, S-, and Se-based organic ligands, tin hydrides, tin sulfides, tin selenides, and mixtures thereof;
   c) a zinc source selected from the group consisting of zinc complexes of N-, O-, C-, S-, and Se-based organic ligands, zinc sulfides, zinc selenides, and mixtures thereof; and
   d) optionally a vehicle, comprising a liquid chalcogen compound, a liquid tin source, a solvent, or a mixture thereof; and
2) a plurality of particles selected from the group consisting of CZTS/Se particles; elemental Cu-, elemental Zn- or elemental Sn-containing particles; binary or ternary Cu-, Zn- or Sn-containing chalcogenide particles; and mixtures thereof.

Another aspect of this invention is a film comprising:

a) an inorganic matrix; and
b) CZTS/Se microparticles characterized by an average longest dimension of 0.5-200 microns, wherein the microparticles are embedded in the inorganic matrix.

Another aspect of this invention is a coated substrate comprising:

a) a substrate; and
b) at least one layer comprising:
i) an inorganic matrix; and
ii) CZTS/Se microparticles characterized by an average longest dimension of 0.5-200 microns, wherein the microparticles are embedded in the inorganic matrix.

Another aspect of this invention is a photovoltaic cell comprising the film as described above.

### BRIEF DESCRIPTION OF THE FIGURES

FIG. 1 depicts an SEM cross-section of a film prepared as described in Example 1, showing CZTS microparticles embedded in a CZTS matrix derived from CZTS molecular precursors.

FIG. 2 depicts the XRD of a film comprising CZTS particles embedded in a CZTS/Se matrix derived from selenized CZTS molecular precursors, as described in Example 1B.

FIG. 3 depicts the XRD of a film annealed under selenium comprising CZTS/Se, prepared from CZTS microcrystals embedded in a matrix derived from CZTS molecular precursors, as described in Example 1C.

FIG. 4 depicts an SEM cross-section of a CZTS/Se film comprising microcrystals embedded in a matrix, as described in Example 1C.

### DETAILED DESCRIPTION

Herein, the terms “solar cell” and “photovoltaic cell” are synonymous unless specifically defined otherwise. These terms refer to devices that use semiconductors to convert visible and near-visible light energy into usable electrical energy. The terms “band gap energy,” “optical band gap,” and “band gap” are synonymous unless specifically defined otherwise. These terms refer to the energy required to generate electron-hole pairs in a semiconductor material, which in general is the minimum energy needed to excite an electron from the valence band to the conduction band.

A subclass of solar cells are monograin layer (MGL) solar cells, also known as monocrystalline and monoparticle membrane solar cells. The MGL consists of monograin powder crystals embedded in an organic resin. A main technological advantage is that the absorber is fabricated separately from the solar cell, which leads to benefits in both the absorber- and cell-stages of MGL production. High temperatures are often preferred in adsorber material production, while lower temperatures are often preferred in the cell production. Fabricating the absorber and then embedding it in a matrix allows the possibility of using inexpensive, flexible, low-temperature substrates in the manufacture of inexpensive flexible solar cells.

Herein, an inorganic matrix replaces the organic matrix used in traditional MGL. As defined herein, “inorganic matrix” refers to a matrix comprising inorganic semiconductors, precursors to inorganic semiconductors, inorganic insulators, precursors to inorganic insulators, or mixtures thereof. Materials designated as inorganic matrixes can also contain small amounts of other materials, including dopants such as sodium, and organic materials. Examples of suitable inorganic matrixes include Cu₂ZnSn(S,Se)₄, Cu(In,Ga)(S,Se)₂, SiO₂, and precursors thereof. The inorganic matrix is used in combination with microparticles of chalcogenide semiconductor to build a coated film. In some embodiments, the bulk of the functionality comes from the microparticles, and the inorganic matrix plays a role in layer formation and enhancement of the layer performance. The longest dimension of the microparticles can be greater than the average thickness of the inorganic matrix and, in some instances, can span the coated thickness. The longest dimension of the microparticles can be less than or equivalent to the coated thickness, resulting in a film with completely or partially embedded microparticles. The microparticles and inorganic matrix can comprise different materials or can consist of essentially the same composition or can vary in composition, e.g., the chalcogenide or dopant composition can vary.

Herein, grain size refers to the diameter of a grain of granular material, wherein the diameter is defined as the longest distance between two points on its surface. In contrast, crystallite size is the size of a single crystal inside the grain. A single grain can be composed of several crystals. A useful method for obtaining grain size is electron microscopy. ASTM test methods are available for determining planar grain size, that is, characterizing the two-dimensional grain sections revealed by the sectioning plane. Manual grain size measurements are described in ASTM E 112 (equiaxed grain structures with a single size distribution) and E 1182 (specimens with a bi-modal grain size distribution); while ASTM E 1382 describes how any grain size type or condition can be measured using image analysis methods.

Herein, element groups are represented utilizing CAS notation. As used herein, the term “chalcogen” refers to Group VIA elements, and the terms “metal chalcogenides” or “chalcogenides” refer to materials that comprise metals and Group VIA elements. Suitable Group VIA elements include sulfur, selenium and tellurium. Metal chalcogenides are important candidate materials for photovoltaic applications, since many of these compounds have optical band gap values well within the terrestrial solar spectra.

Herein, the term “binary-metal chalcogenide” refers to a chalcogenide composition comprising one metal. The term “ternary-metal chalcogenide” refers to a chalcogenide composition comprising two metals. The term “quaternary-metal chalcogenide” refers to a chalcogenide composition comprising three metals. The term “multinary-metal chalcogenide” refers to a chalcogenide composition comprising two or more metals, and encompasses ternary and quaternary metal chalcogenide compositions.

Herein, the terms “copper tin sulfide” and “CTS” refer to Cu₂SnS₃. “Copper tin selenide” and “CTSe” refer to Cu₂SnSe₃. “Copper tin sulfide/selenide,” “CTS/Se,” and “CTS-Se” encompass all possible combinations of Cu₂Sn(S,Se)₃, including Cu₂SnS₃, Cu₂SnSe₃, and Cu₂SnSₓSe₃₋ₓ, where 0≦x≦3. The terms “copper tin sulfide,” “copper tin selenide,” “copper tin sulfide/selenide,” “CTS,” “CTSe,” “CTS/Se” and “CTS-Se” further encompass fractional stoichiometries, e.g., Cu_{2.80}Sn_{1.05}S₃. That is, the stoichiometry of the elements can vary from a strictly 2:1:3 molar ratio. Similarly, the terms “Cu₂S/Se,” “CuS/Se,” “Cu₄Sn(S/Se)₄,” “Sn(S/Se)₂,” “SnS/Se,” and “ZnS/Se” encompass fractional stoichiometries and all possible combinations of Cu₂(S_{y}Se_{1-y}), Cu(S_{y}Se_{1-y}), Cu₄Sn(S_{y}Se_{1-y})₄, Sn(S_{y}Se_{1-y})₂, Sn(S_{y}Se_{1-y}), and Zn(S_{y}Se_{1-y}) from 0≦y≦1.

Herein, the terms “copper zinc tin sulfide” and “CZTS” refer to Cu₂ZnSnS₄. “Copper zinc tin selenide” and “CZTSe” refer to Cu₂ZnSnSe₄. “Copper zinc tin sulfide/selenide,” “CZTS/Se,” and “CZTS-Se” encompass all possible combinations of Cu₂ZnSn(S,Se)₄, including Cu₂ZnSnS₄, Cu₂ZnSnSe₄, and Cu₂ZnSnSₓSe₄₋ₓ, where 0≦x≦4. The terms “CZTS,” “CZTSe,” “CZTS/Se,” and “CZTS-Se” further encompass copper zinc tin sulfide/selenide semiconductors with fractional stoichiometries, e.g., Cu_{1.94}Zn_{0.63}Sn_{1.3}S₄. That is, the stoichiometry of the elements can vary from a strictly 2:1:1:4 molar ratio. Materials designated as CZTS-Se can also contain small amounts of other elements such as sodium. In addition, the Cu, Zn and Sn in CZTS/Se can be partially substituted by other metals. That is, Cu can be partially replaced by Ag and/or Au; Zn by Fe, Cd and/or Hg; and Sn by C, Si, Ge and/or Pb.

To date, the highest efficiencies have been measured for copper-poor CZTS-Se solar cells, where by “copper-poor” it is understood that the ratio Cu/(Zn+Sn) is less than 1.0. For high efficiency devices, a molar ratio of zinc to tin greater than one is also desirable.

The term “kesterite” is commonly used to refer to materials belonging to the kesterite family of minerals and is also the common name of the mineral CZTS. As used herein, the term “kesterite” refers to crystalline compounds in either the I4- or I4-2m space groups having the nominal formula Cu₂ZnSn(S,Se)₄. It also refers to “atypical kesterites,” wherein zinc has replaced a fraction of the copper, or copper has replaced a fraction of the zinc, to give Cu_{c}Zn_{z}Sn(S,Se)₄, wherein c is greater than two and z is less than one, or c is less than two and z is greater than one. The term “kesterite structure” refers to the structure of these compounds.

As used herein, “coherent domain size” refers to the size of crystalline domains over which a defect-free, coherent structure can exist. The coherency comes from the fact that the three-dimensional ordering is not broken inside of these domains. When the coherent grain size is less than about 100 nm in size, appreciable broadening of the x-ray diffraction lines will occur. The domain size can be estimated by measuring the full width at half maximum intensity of the diffraction peak.

Herein the terms “nanoparticle,” “nanocrystal,” and “nanocrystalline particle” are synonymous unless specifically defined otherwise, and are meant to include nanoparticles with a variety of shapes that are characterized by an average longest dimension of about 1 nm to about 500 nm. Herein, by nanoparticle “size” or “size range” or “size distribution,” we mean that the average longest dimension of a plurality of nanoparticles falls within the range. “Longest dimension” is defined herein as the measurement of a nanoparticle from end to end. The “longest dimension” of a particle will depend on the shape of the particle. For example, for particles that are roughly or substantially spherical, the longest dimension will be a diameter of the particle. For other particles, the longest dimension can be a diagonal or a side.

Herein the terms “microparticle”, “microcrystal”, and “microcrystalline particle” are synonymous unless specifically defined otherwise and are meant to include microparticles with a variety of shapes that are characterized by an average longest dimension of at least about 0.5 to about 10 microns. Herein, microparticle “size” or “size range” or “size distribution” are defined the same as described above for nanoparticles.

As defined herein, “coated particles” refers to particles that have a surface coating of organic or inorganic material. Methods for surface-coating inorganic particles are well-known in the art. As defined herein, the terms “surface coating” and “capping agent” are used synonymously and refer to a strongly absorbed or chemically bonded monolayer of organic or inorganic molecules on the surface of the particle(s). In addition to carbon and hydrogen, suitable organic capping agents can comprise functional groups, including nitrogen-, oxygen-, sulfur-, selenium-, and phosphorus-based functional groups. Suitable inorganic capping agents can comprise chalcogenides, including metal chalcogenides, and zintl ions, wherein zintl ions refers to homopolyatomic anions and heteropolyatomic anions that have intermetallic bonds between the same or different metals of the main group, transition metals, lanthanides, and/or actinides.

Elemental and metal chalcogenide particles can be composed only of the specified elements or can be doped with small amounts of other elements. As used herein, the term “alloy” refers to a substance that is a mixture, as by fusion, of two or more metals. Throughout the specification, all reference to wt % of particles is meant to include the surface coating. Many suppliers of nanoparticles use undisclosed or proprietary surface coatings that act as dispersing aids. Throughout the specification, all reference to wt % of particles is meant to include the undisclosed or proprietary coatings that the manufacturer may, or may not, add as a dispersant aid. For instance, a commercial copper nanopowder is considered nominally 100 wt % copper.

Herein, the term “metal salts” refers to compositions wherein metal cations and inorganic anions are joined by ionic bonding. Relevant classes of inorganic anions comprise oxides, sulfides, selenides, carbonates, sulfates and halides. Herein, the term “metal complexes” refers to compositions wherein a metal is bonded to a surrounding array of molecules or anions, typically called “ligands” or “complexing agents.” The atom within a ligand that is directly bonded to the metal atom or ion is called the “donor atom” and, herein, often comprises nitrogen, oxygen, selenium, or sulfur.

Herein, ligands are classified according to M. L. H. Green's “Covalent Bond Classification (CBC) Method.” An “X-function ligand” is one which interacts with a metal center via a normal 2-electron covalent bond, composed of 1 electron from the metal and 1 electron from the X ligand. Simple examples of X-type ligands include alkyls and thiolates. Herein, the term “nitrogen-, oxygen-, carbon-, sulfur-, and selenium-based organic ligands” refers specifically to carbon-containing X-function ligands, wherein the donor atom comprises nitrogen, oxygen, carbon, sulfur, or selenium. Herein, the term “complexes of nitrogen-, oxygen-, carbon-, sulfur-, and selenium-based organic ligands” refers to the metal complexes comprising these ligands. Examples include metal complexes of amidos, alkoxides, acetylacetonates, acetates, carboxylates, hydrocarbyls, O-, N-, S-, Se-, and halogen-substituted hydrocarbyls, thiolates, selenolates, thiocarboxylates, selenocarboxylates, dithiocarbamates, and diselenocarbamates.

As defined herein, a “hydrocarbyl group” is a univalent group containing only carbon and hydrogen. Examples of hydrocarbyl groups include unsubstituted alkyls, cycloalkyls, and aryl groups, including alkyl-substituted aryl groups. Suitable hydrocarbyl groups and alkyl groups contain 1 to about 30 carbons, or 1 to 25, 1 to 20, 1 to 15, 1 to 10, 1 to 5, 1 to 4, or 1 to 2 carbons. By “heteroatom-substituted hydrocarbyl” is meant a hydrocarbyl group that contains one or more heteroatoms, where the free valence is located on carbon, not on the heteroatom. Examples include hydroxyethyl and carbomethoxyethyl. Suitable heteroatom substituents include O-, N-, S-, halogen-, and tri(hydrocarbyl)silyl. In a substituted hydrocarbyl, all of the hydrogens can be substituted, as in trifluoromethyl. Herein, the term “tri(hydrocarbyl)silyl” encompasses silyl substituents, wherein the substituents on silicon are hydrocarbyls.

Herein, by “O-, N-, S-, and Se-based functional groups” is meant univalent groups other than hydrocarbyl and substituted hydrocarbyl that comprise O-, N-, S-, or Se-heteroatoms, wherein the free valence is located on this heteroatom. Examples of O-, N-, S-, and Se-based functional groups include alkoxides, amidos, thiolates, and selenolates.

### Inks

One aspect of this invention is an ink comprising:

a) a molecular precursor to CZTS/Se, comprising:
i) a copper source selected from the group consisting of copper complexes of N-, O-, C-, S-, and Se-based organic ligands, copper sulfides, copper selenides, and mixtures thereof;
ii) a tin source selected from the group consisting of tin complexes of N-, O-, C-, S-, and Se-based organic ligands, tin hydrides, tin sulfides, tin selenides, and mixtures thereof;
iii) a zinc source selected from the group consisting of zinc complexes of N-, O-, C-, S-, and Se-based organic ligands, zinc sulfides, zinc selenides, and mixtures thereof; and
iv) a vehicle, comprising a liquid chalcogen compound, a liquid tin source, a solvent, or a mixture thereof; and
   b) a plurality of particles selected from the group consisting of: CZTS/Se particles; elemental Cu-, Zn- or Sn-containing particles; binary or ternary Cu-, Zn- or Sn-containing chalcogenide particles; and mixtures thereof.

This ink is referred to as a CZTS/Se precursor ink, as it contains the precursors for forming a CZTS/Se thin film. In some embodiments, the molecular precursor to CZTS/Se consists essentially of components (i)-(iv) and the ink consists essentially of components (a)-(b).

Another aspect of this invention is a process for forming a coated substrate comprising disposing an ink onto a substrate, wherein the ink comprises:

a) a molecular precursor to CZTS/Se, comprising:
i) a copper source selected from the group consisting of copper complexes of N-, O-, C-, S-, and Se-based organic ligands, copper sulfides, copper selenides, and mixtures thereof;
ii) a tin source selected from the group consisting of tin complexes of N-, O-, C-, S-, and Se-based organic ligands, tin hydrides, tin sulfides, tin selenides, and mixtures thereof;
iii) a zinc source selected from the group consisting of zinc complexes of N-, O-, C-, S-, and Se-based organic ligands, zinc sulfides, zinc selenides, and mixtures thereof; and
iv) a vehicle, comprising a liquid chalcogen compound, a liquid tin source, a solvent, or a mixture thereof; and
   b) a plurality of particles selected from the group consisting of:

CZTS/Se particles; elemental Cu-, Zn- or Sn-containing particles; binary or ternary Cu-, Zn- or Sn-containing chalcogenide particles; and mixtures thereof.

Chalcogen Compounds.

In some embodiments, the molecular precursor further comprises a chalcogen compound. Suitable chalcogen compounds include: elemental S, elemental Se, CS₂, CSe₂, CSSe, R¹S—Z, R¹Se—Z, R¹S—SR¹, R¹Se—SeR¹, R²C(S)S—Z, R²C(Se)Se—Z, R²C(Se)S—Z, R¹C(O)S—Z, R¹C(O)Se—Z, and mixtures thereof, with each Z independently selected from the group consisting of: H, NR⁴₄, and SiR⁵₃; wherein each R¹ and R⁵ is independently selected from the group consisting of: hydrocarbyl and O-, N-, S-, Se-, halogen- and tri(hydrocarbyl)silyl-substituted hydrocarbyl; each R² is independently selected from the group consisting of hydrocarbyl, O-, N-, S-, Se-, halogen-, and tri(hydrocarbyl)silyl-substituted hydrocarbyl, and O-, N-, S-, and Se-based functional groups; and each R⁴ is independently selected from the group consisting of hydrogen, O-, N-, S-, Se-, halogen- and tri(hydrocarbyl)silyl-substituted hydrocarbyl, and O-, N-, S-, and Se-based functional groups. In some embodiments, elemental sulfur, elemental selenium, or a mixture of elemental sulfur and selenium is present.

For the chalcogen compounds, suitable R¹S—SR¹, R¹Se—SeR¹ include: dimethyldisulfide, 2,2′-dipyridyldisulfide, di(2-thienyl)disulfide, bis(2-hydroxyethyl)disulfide, bis(2-methyl-3-furyl)disulfide, bis(6-hydroxy-2-naphthyl)disulfide, diethyldisulfide, methylpropyldisulfide, diallyldisulfide, dipropyldisulfide, isopropyldisulfide, dibutyldisulfide, sec-butyldisulfide, bis(4-methoxyphenyl)disulfide, dibenzyldisulfide, p-tolyldisulfide, phenylacetyldisulfide, tetramethylthiuram disulfide, tetraethylthiuram disulfide, tetrapropylthiuram disulfide, tetrabutylthiuram disulfide, methylxanthic disulfide, ethylxanthic disulfide, i-propylxanthic disulfide, dibenzyldiselenide, dimethyldiselenide, diethylselenide, diphenyldiselenide, and mixtures thereof.

For the chalcogen compounds, suitable R²C(S)S—Z, R²C(Se)Se—Z, R²C(Se)S—Z, R¹C(O)S—Z, and R¹C(O)Se—Z are selected from the below lists of suitable thiO-, selenO-, and dithiocarboxylates; suitable dithiO-, diselenO-, and thioselenocarbamates; and suitable dithioxanthogenates.

Suitable NR⁴₄ include: Et₂NH₂, Et₄N, Et₃NH, EtNH₃, NH₄, Me₂NH₂, Me₄N, Me₃NH, MeNH₃, Pr₂NH₂, Pr₄N, Pr₃NH, PrNH₃, Bu₃NH, Me₂PrNH, (i-Pr)₃NH, and mixtures thereof.

Suitable SiR⁵₃ include: SiMe₃, SiEt₃, SiPr₃, SiBu₃, Si(i-Pr)₃, SiEtMe₂, SiMe₂(i-Pr), Si(t-Bu)Me₂, Si(cyclohexyl)Me₂, and mixtures thereof.

Many of these chalcogen compounds are commercially available or readily synthesized by the addition of an amine, alcohol, or alkyl nucleophile to CS₂ or CSe₂ or CSSe.

Molar Ratios of the Ink.

In some embodiments, the molar ratio of Cu:Zn:Sn is about 2:1:1 in the ink. In some embodiments, the molar ratio of Cu to (Zn+Sn) is less than one in the ink. In some embodiments, the molar ratio of Zn to Sn is greater than one in the ink. These embodiments are encompassed by the term “a molar ratio of Cu:Zn:Sn is about 2:1:1,” which covers a range of compositions such as Cu:Zn:Sn ratios of 1.75:1:1.35 and 1.78:1:1.26. In some embodiments, the ratio of Cu, Zn, and Sn can deviate from a 2:1:1 molar ratio by +/−40 mole %, +/−30 mole %, +/−20 mole %, +/−10 mole %, or +/−5 mole %.

In some embodiments, the molar ratio of total chalcogen to (Cu+Zn+Sn) is at least about 1 in the ink. As defined herein, sources for the total chalcogen include the metal chalcogenides (e.g., the copper, tin and zinc sulfides and selenides of the molecular precursor, the CZTS/Se particles, the binary Cu-, Zn- or Sn-containing chalcogenide particles, and the ternary Cu-, Zn-, or Sn-containing chalcogenide particles) and the sulfur- and selenium-based organic ligands and the optional chalcogen compound of the molecular precursor.

As defined herein, the moles of total chalcogen are determined by multiplying the moles of each metal chalcogenide by the number of equivalents of chalcogen that it contains and then summing these quantities together with the number of moles of any sulfur and selenium-based organic ligands and optional chalcogen compound. Each sulfur- and selenium-based organic ligand and compound is assumed to contribute just one equivalent of chalcogen in this determination of total chalcogen. This is because not all of the chalcogen atoms contained within each ligand and compound will necessarily be available for incorporation into CZTS/Se; some of the chalcogen atoms from these sources can be incorporated into organic by-products.

The moles of (Cu+Zn+Sn) are determined by multiplying the moles of each Cu-, or Zn- or Sn-containing species by the number of equivalents of Cu or Zn or Sn that it contains and then summing these quantities. As an example, the molar ratio of total chalcogen to (Cu+Zn+Sn) for an ink comprising zinc acetate, copper(II).dimethyldithiocarbamate (CuDTC), tin(II) acetate, 2-mercaptoethanol (MCE), sulfur, Cu₂S particles, Zn particles, and SnS₂ particles=[2(moles of CuDTC)+(moles of MCE)+(moles of S)+(moles of Cu₂S)+2(moles of SnS₂)]/[(moles of Zn acetate)+(moles of CuDTC)+(moles of Sn(II) acetate)+2(moles of Cu₂S)+(moles of Zn)+(moles of SnS₂)].

### Molecular Precursor

Molar Ratios of the Molecular Precursor.

In some embodiments, the molar ratio of Cu:Zn:Sn is about 2:1:1 in the molecular precursor. In some embodiments, the molar ratio of Cu to (Zn+Sn) is less than one in the molecular precursor. In some embodiments, the molar ratio of Zn to Sn is greater than one in the molecular precursor. In some embodiments, the ratio of Cu, Zn, and Sn can deviate from a 2:1:1 molar ratio by +/−40 mole %, +/−30 mole %, +/−20 mole %, +/−10 mole %, or +/−5 mole %.

In some embodiments, the molar ratio of total chalcogen to (Cu+Zn+Sn) is at least about 1 in the molecular precursor, and is determined as defined above for the ink.

In some embodiments, elemental sulfur, elemental selenium, or a mixture of elemental sulfur and selenium is present in the molecular precursor, and the molar ratio of elemental (S+Se) is about 0.2 to about 5, or about 0.5 to about 2.5, relative to the tin source of the molecular precursor.

Organic Ligands.

In some embodiments, the nitrogen-, oxygen-, carbon-, sulfur- and selenium-based organic ligands are selected from the group consisting of: amidos; alkoxides; acetylacetonates; carboxylates; hydrocarbyls; O-, N-, S-, Se-, halogen-, and tri(hydrocarbyl)silyl-substituted hydrocarbyls; thio- and selenolates; thiO-, selenO-, and dithiocarboxylates; dithiO-, diselenO-, and thioselenocarbamates; and dithioxanthogenates. Many of these are commercially available or readily synthesized by the addition of an amine, alcohol, or alkyl nucleophile to CS₂ or CSe₂ or CSSe.

Amidos.

Suitable amidos include: bis(trimethylsilyl)amino, dimethylamino, diethylamino, diisopropylamino, N-methyl-t-butylamino, 2-(dimethylamino)-N-methylethylamino, N-methylcyclohexylamino, dicyclohexylamino, N-ethyl-2-methylallylamino, bis(2-methoxyethyl)amino, 2-methylaminomethyl-1,3-dioxolane, pyrrolidino, t-butyl-1-piperazinocarboxylate, N-methylanilino, N-phenylbenzylamino, N-ethyl-o-toluidino, bis(2,2,2-trifluoromethyl)amino, N-t-butyltrimethylsilylamino, and mixtures thereof. Some ligands can chelate the metal center, and, in some cases, comprise more than one type of donor atom, e.g., the dianion of N-benzyl-2-aminoethanol is a suitable ligand comprising both amino and alkoxide groups.

Alkoxides.

Suitable alkoxides include: methoxide, ethoxide, n-propoxide, i-propoxide, n-butoxide, t-butoxide, neopentoxide, ethylene glycol dialkoxide, 1-methylcyclopentoxide, 2-fluoroethoxide, 2,2,2,-trifluoroethoxide, 2-ethoxyethoxide, 2-methoxyethoxide, 3-methoxy-1-butoxide, methoxyethoxyethoxide, 3,3-diethoxy-1-propoxide, 2-dimethylaminoethoxide, 2-diethylaminoethoxide, 3-dimethylamino-1-propoxide, 3-diethylamino-1-propoxide, 1-dimethylamino-2-propoxide, 1-diethylamino-2-propoxide, 2-(1-pyrrolidinyl)ethoxide, 1-ethyl-3-pyrrolidinoxide, 3-acetyl-1-propoxide, 4-methoxyphenoxide, 4-chlorophenoxide, 4-t-butylphenoxide, 4-cyclopentylphenoxide, 4-ethylphenoxide, 3,5-bis(trifluoromethyl)phenoxide, 3-chloro-5-methoxyphenoxide, 3,5-dimethoxyphenoxide, 2,4,6-trimethylphenoxide, 3,4,5-trimethylphenoxide, 3,4,5-trimethoxyphenoxide, 4-t-butyl-catecholate(2-), 4-propanoylphenoxide, 4-(ethoxycarbonyl)phenoxide, 3-(methylthio)-1-propoxide, 2-(ethylthio)-1-ethoxide, 2-(methylthio)ethoxide, 4-(methylthio)-1-butoxide, 3-(methylthio)-1-hexoxide, 2-methoxybenzylalkoxide, 2-(trimethylsilyl)ethoxide, (trimethylsilyl)methoxide, 1-(trimethylsilyl)ethoxide, 3-(trimethylsilyl)propoxide, 3-methylthio-1-propoxide, and mixtures thereof.

Acetylacetonates. Herein, the term acetylacetonate refers to the anion of 1,3-dicarbonyl compounds, A¹C(O)CH(A²)C(O)A¹, wherein each A¹ is independently selected from hydrocarbyl, substituted hydrocarbyl, and O-, S-, and N-based functional groups and each A² is independently selected from hydrocarbyl, substituted hydrocarbyl, halogen, and O-, S-, and N-based functional groups. Suitable acetylacetonates include: 2,4-pentanedionate, 3-methyl-2-4-pentanedionate, 3-ethyl-2,4-pentanedionate, 3-chloro-2,4-pentanedionate, 1,1,1-trifluoro-2,4-pentanedionate, 1,1,1,5,5,5-hexafluoro-2,4-pentanedionate, 1,1,1,5,5,6,6,6-octafluoro-2,4-hexanedionate, ethyl 4,4,4-trifluoroacetoacetate, 2-methoxyethylacetoacetate, methylacetoacetate, ethylacetoacetate, t-butylacetoacetate, 1-phenyl-1,3-butanedionate, 2,2,6,6-tetramethyl-3,5-heptanedionate, allyloxyethoxytrifluoroacetoacetate, 4,4,4-trifluoro-1-phenyl-1,3-butanedionate, 1,3-diphenyl-1,3-propanedionate, 6,6,7,7,8,8,8-heptafluoro-2-2-dimethyl-3,5-octanedionate, and mixtures thereof.

Carboxylates.

Suitable carboxylates include: acetate, trifluoroacetate, propionate, butyrates, hexanoate, octanoate, decanoate, stearate, isobutyrate, t-butylacetate, heptafluorobutyrate, methoxyacetate, ethoxyacetate, methoxypropionate, 2-ethyl hexanoate, 2-(2-methoxyethoxy)acetate, 2-[2-(2-methoxyethoxy)ethoxy]acetate, (methylthio)acetate, tetrahydro-2-furoate, 4-acetyl butyrate, phenylacetate, 3-methoxyphenylacetate, (trimethylsilyl)acetate, 3-(trimethylsilyl)propionate, maleate, benzoate, acetylenedicarboxylate, and mixtures thereof.

Hydrocarbyls.

Suitable hydrocarbyls include: methyl, ethyl, n-propyl, i-propyl, n-butyl, i-butyl, sec-butyl, t-butyl, n-pentyl, n-hexyl, n-heptyl, n-octyl, neopentyl, 3-methylbutyl, phenyl, benzyl, 4-t-butylbenzyl, 4-t-butylphenyl, p-tolyl, 2-methyl-2-phenylpropyl, 2-mesityl, 2-phenylethyl, 2-ethylhexyl, 2-methyl-2-phenylpropyl, 3,7-dimethyloctyl, allyl, vinyl, cyclopentyl, cyclohexyl, and mixtures thereof.

Substituted Hydrocarbyls.

Suitable O-, N-, S-, halogen- and tri(hydrocarbyl)silyl-substituted hydrocarbyls include: 2-methoxyethyl, 2-ethoxyethyl, 4-methoxyphenyl, 2-methoxybenzyl, 3-methoxy-1-butyl, 1,3-dioxan-2-ylethyl, 3-trifluoromethoxyphenyl, 3,4-(methylenedioxy)phenyl, 2,4-dimethoxyphenyl, 2,5-dimethoxyphenyl, 3,4-dimethoxyphenyl, 2-methoxybenzyl, 3-methoxybenzyl, 4-methoxybenzyl, 3,5-dimethoxyphenyl, 3,5-dimethyl-4-methoxyphenyl, 3,4,5-trimethoxyphenyl, 4-methoxyphenethyl, 3,5-dimethoxybenzyl, 4-(2-tetrahydro-2H-pyranoxy)phenyl, 4-phenoxyphenyl, 2-benzyloxyphenyl, 3-benzyloxyphenyl, 4-benzyloxyphenyl, 3-fluoro-4-methoxyphenyl, 5-fluoro-2-methoxyphenyl, 2-ethoxyethenyl, 1-ethoxyvinyl, 3-methyl-2-butenyl, 2-furyl, carbomethoxyethyl, 3-dimethylamino-1-propyl, 3-diethylamino-1-propyl, 3-[bis(trimethylsilyl)amino]phenyl, 4-(N,N-dimethyl)aniline, [2-(1-pyrrolidinylmethyl)phenyl], [3-(1-pyrrolidinylmethyl)phenyl], [4-(1-pyrrolidinylmethyl)phenyl], [2-(4-morpholinylmethyl)phenyl], [3-(4-morpholinylmethyl)phenyl], [4-(4-morpholinylmethyl)phenyl], (4-(1-piperidinylmethyl)phenyl), (2-(1-piperidinylmethyl)phenyl), (3-(1-piperidinylmethyl)phenyl), 3-(1,4-dioxa-8-azaspiro[4,5]dec-8-ylmethyl)phenyl, 1-methyl-2-pyrrolyl, 2-fluoro-3-pyridyl, 6-methoxy-2-pyrimidyl, 3-pyridyl, 5-bromo-2-pyridyl, 1-methyl-5-imidazolyl, 2-chloro-5-pyrimidyl, 2,6-dichloro-3-pyrazinyl, 2-oxazolyl, 5-pyrimidyl, 2-pyridyl, 2-(ethylthio)ethyl, 2-(methylthio)ethyl, 4-(methylthio)butyl, 3-(methylthio)-1-hexyl, 4-thioanisole, 4-bromo-2-thiazolyl, 2-thiophenyl, chloromethyl, 4-fluorophenyl, 3-fluorophenyl, 4-chlorophenyl, 3-chlorophenyl, 4-fluoro-3-methylphenyl, 4-fluoro-2-methylphenyl, 4-fluoro-3-methylphenyl, 5-fluoro-2-methylphenyl, 3-fluoro-2-methylphenyl, 4-chloro-2-methylphenyl, 3-fluoro-4-methylphenyl, 3,5-bis(trifluoromethyl)-phenyl, 3,4,5-trifluorophenyl, 3-chloro-4-fluorophenyl, 3-chloro-5-fluorophenyl, 4-chloro-3-fluorophenyl, 3,4-dichlorophenyl, 3,5-dichlorophenyl, 3,4-difluorophenyl, 3,5-difluorophenyl, 2-bromobenzyl, 3-bromobenzyl, 4-fluorobenzyl, perfluoroethyl, 2-(trimethylsilyl)ethyl, (trimethylsilyl)methyl, 3-(trimethylsilyl)propyl, and mixtures thereof.

Thio- and Selenolates.

Suitable thio- and selenolates include: 1-thioglycerol, phenylthio, ethylthio, methylthio, n-propylthio, i-propylthio, n-butylthio, i-butylthio, t-butylthio, n-pentylthio, n-hexylthio, n-heptylthio, n-octylthio, n-nonylthio, n-decylthio, n-dodecylthio, 2-methoxyethylthio, 2-ethoxyethylthio, 1,2-ethanedithiolate, 2-pyridinethiolate, 3,5-bis(trifluoromethyl)benzenethiolate, toluene-3,4-dithiolate, 1,2-benzenedithiolate, 2-dimethylaminoethanethiolate, 2-diethylaminoethanethiolate, 2-propene-1-thiolate, 2-hydroxythiolate, 3-hydroxythiolate, methyl-3-mercaptopropionate anion, cyclopentanethiolate, 2-(2-methoxyethoxy)ethanethiolate, 2-(trimethylsilyl)ethanethiolate, pentafluorophenylthiolate, 3,5-dichlorobenzenethiolate, phenylthiolate, cyclohexanethiolate, 4-chlorobenzenemethanethiolate, 4-fluorobenzenemethanethiolate, 2-methoxybenzenethiolate, 4-methoxybenzenethiolate, benzylthiolate, 3-methylbenzylthiolate, 3-ethoxybenzenethiolate, 2,5-dimethoxybenzenethiolate, 2-phenylethanethiolate, 4-t-butylbenzenethiolate, 4-t-butylbenzylthiolate, phenylselenolate, methylselenolate, ethylselenolate, n-propylselenolate, i-propylselenolate, n-butylselenolate, i-butylselenolate, t-butylselenolate, pentylselenolate, hexylselenolate, octylselenolate, benzylselenolate, and mixtures thereof.

Carboxylates, Carbamates, and Xanthogenates.

Suitable thiO-, selenO-, and dithiocarboxylates include: thioacetate, thiobenzoate, selenobenzoate, dithiobenzoate, and mixtures thereof. Suitable dithiO-, diselenO-, and thioselenocarbamates include: dimethyldithiocarbamate, diethyldithiocarbamate, dipropyldithiocarbamate, dibutyldithiocarbamate, bis(hydroxyethyl)dithiocarbamate, dibenzyldithiocarbamate, dimethyldiselenocarbamate, diethyldiselenocarbamate, dipropyldiselenocarbamate, dibutyldiselenocarbamate, dibenzyldiselenocarbamate, and mixtures thereof. Suitable dithioxanthogenates include: methylxanthogenate, ethylxanthogenate, i-propylxanthogenate, and mixtures thereof.

Vehicle.

The molecular precursor comprises a vehicle, comprising a liquid chalcogen compound, a liquid tin source, a solvent, or a mixture thereof. Components and by-products of the molecular precursor can be liquids at room temperature or at the heating temperature and coating temperature. In such cases, the molecular precursor need not comprise a solvent. In some embodiments, a chalcogen compound is present and is a liquid at room temperature. In other embodiments, the tin source is a liquid at room temperature. In yet other embodiments, a chalcogen compound is present and is a liquid at room temperature and the tin source is a liquid at room temperature. In some embodiments, the vehicle comprises about 95 to about 5 wt %, 90 to 10 wt %, 80 to 20 wt %, 70 to 30 wt %, or 60 to 40 wt % of the molecular precursor, based upon the total weight of the molecular precursor.

Solvents.

In some embodiments, the vehicle comprises a solvent. In some embodiments, the boiling point of the solvent is greater than about 100° C., 110° C., 120° C., 130° C., 140° C., 150° C., 160° C., 170° C., 180° C. or 190° C. at atmospheric pressure. In some embodiments, the process is conducted at atmospheric pressure. Suitable solvents include: aromatics, heteroaromatics, nitriles, amides, alcohols, pyrrolidinones, amines, thiols, and mixtures thereof. Suitable heteroaromatics include pyridine and substituted pyridines. Suitable amines include compounds of the form R⁶NH₂, wherein each R⁶ is independently selected from the group consisting of: O-, N-, S-, and Se-substituted hydrocarbyl. In some embodiments, the solvent comprises an amino-substituted pyridine.

Aromatics.

Suitable aromatic solvents include: benzene, toluene, ethylbenzene, chlorobenzene, o-xylene, m-xylene, p-xylene, mesitylene, i-propylbenzene, 1-chlorobenzene, 2-chlorotoluene, 3-chlorotoluene, 4-chlorotoluene, t-butylbenzene, n-butylbenzene, i-butylbenzene, s-butylbenzene, 1,2-dichlorobenzene, 1,3-dichlorobenzene, 1,4-dichlorobenzene, 1,3-diisopropylbenzene, 1,4-diisopropylbenzene, 1,2-difluorobenzene, 1,2,4-trichlorobenzene, 3-methylanisole, 3-chloroanisole, 3-phenoxytoluene, diphenylether, and mixtures thereof.

Heteroaromatics.

Suitable heteroaromatic solvents include: pyridine, 2-picoline, 3-picoline, 3,5-lutidine, 4-t-butylpyridine, 2-aminopyridine, 3-aminopyridine, diethylnicotinamide, 3-cyanopyridine, 3-fluoropyridine, 3-chloropyridine, 2,3-dichloropyridine, 2,5-dichloropyridine, 5,6,7,8-tetrahydroisoquinoline, 6-chloro-2-picoline, 2-methoxypyridine, 3-(aminomethyl)pyridine, 2-amino-3-picoline, 2-amino-6-picoline, 2-amino-2-chloropyridine, 2,3-diaminopyridine, 3,4-diaminopyridine, 2-(methylamino)pyridine, 2-dimethylaminopyridine, 2-(aminomethyl)pyridine, 2-(2-aminoethyl)pyridine, 2-methoxypyridine, 2-butoxypyridine, and mixtures thereof.

Nitriles.

Suitable nitrile solvents include: acetonitrile, 3-ethoxypropionitrile, 2,2-diethoxypropionitrile, 3,3-diethoxypropionitrile, diethoxyacetonitrile, 3,3-dimethoxypropionitrile, 3-cyanopropionaldehyde dimethylacetal, dimethylcyanamide, diethylcyanamide, diisopropylcyanamide, 1-pyrrolidinecarbonitrile, 1-piperidinecarbonitrile, 4-morpholinecarbonitrile, methylaminoacetonitrile, butylaminoacetonitrile, dimethylaminoacetonitrile, diethylaminoacetonitrile, N-methyl-beta-alaninenitrile, 3,3′-iminopropionitrile, 3-(dimethylamino)propionitrile, 1-piperidinepropionitrile, 1-pyrrolidinebutyronitrile, propionitrile, butyronitrile, valeronitrile, isovaleronitrile, 3-methoxypropionitrile, 3-cyanopyridine, 4-amino-2-chlorobenzonitrile, 4-acetylbenzonitrile, and mixtures thereof.

Amides.

Suitable amide solvents include: N,N-diethylnicotinamide, N-methylnicotinamide, N,N-dimethylformamide, N,N-diethylformamide, N,N-diisopropylformamide, N,N-dibutylformamide, N,N-dimethylacetamide, N,N-diethylacetamide, N,N-diisopropylacetamide, N,N-dimethylpropionamide, N,N-diethylpropionamide, N,N,2-trimethylpropionamide, acetamide, propionamide, isobutyramide, trimethylacetamide, nipecotamide, N,N-diethylnipecotamide, and mixtures thereof.

Alcohols. Suitable alcohol solvents include: methoxyethoxyethanol, methanol, ethanol, isopropanol, 1-butanol, 2-pentanol, 2-hexanol, 2-octanol, 2-nonanol, 2-decanol, 2-dodecanol, ethylene glycol, 1,3-propanediol, 2,3-butanediol, 1,5-pentanediol, 1,6-hexanediol, 1,7-heptanediol, 1,8-octanediol, cyclopentanol, cyclohexanol, cyclopentanemethanol, 3-cyclopentyl-1-propanol, 1-methylcyclopentanol, 3-methylcyclopentanol, 1,3-cyclopentanediol, 2-cyclohexylethanol, 1-cyclohexylethanol, 2,3-dimethylcyclohexanol, 1,3-cyclohexanediol, 1,4-cyclohexanediol, cycloheptanol, cyclooctanol, 1,5-decalindiol, 2,2-dichloroethanol, 2,2,2-trifluoroethanol, 2-methoxyethanol, 2-ethoxyethanol, 2-propoxyethanol, 2-butoxyethanol, 3-ethoxy-1-propanol, propyleneglycol propyl ether, 3-methoxy-1-butanol, 3-methoxy-3-methyl-1-butanol, 3-ethoxy-1,2-propanediol, di(ethyleneglycol) ethylether, diethylene glycol, 2,4-dimethylphenol, and mixtures thereof.

Pyrrolidinones. Suitable pyrrolidinone solvents include: N-methyl-2-pyrrolidinone, 5-methyl-2-pyrrolidinone, 3-methyl-2-pyrrolidinone, 2-pyrrolidinone, 1,5-dimethyl-2-pyrrolidinone, 1-ethyl-2-pyrrolidinone, 1-(2-hydroxyethyl)-2-pyrrolidinone, 5-methoxy-2-pyrrolidinone, 1-(3-aminopropyl)-2-pyrrolidinone, and mixtures thereof.

Amines. Suitable amine solvents include: butylamine, hexylamine, octylamine, 3-methoxypropylamine, 2-methylbutylamine, isoamylamine, 1,2-dimethylpropylamine, hydrazine, ethylenediamine, 1,3-diaminopropane, 1,2-diaminopropane, 1,2-diamino-2-methylpropane, 1,3-diaminopentane, 1,1-dimethylhydrazine, N-ethylmethylamine, diethylamine, N-methylpropylamine, diisopropylamine, dibutylamine, triethylamine, N-methylethylenediamine, N-ethylethylenediamine, N-propylethylenediamine, N-isopropylethylenediamine, N,N′-dimethylethylenediamine, N,N-dimethylethylenediamine, N,N′-diethylethylenediamine, N,N-diethylethylenediamine, N,N-diisopropylethylenediamine, N,N-dibutylethylenediamine, N,N,N′-trimethylethylenediamine, 3-dimethylaminopropylamine, 3-diethylaminopropylamine, diethylenetriamine, cyclohexylamine, bis(2-methoxyethyl)amine, aminoacetaldehyde diethyl acetal, methylaminoacetaldehyde dimethyl acetal, N,N-dimethylacetamide dimethyl acetal, dimethylaminoacetaldehyde diethyl acetal, diethylaminoacetaldehyde diethyl acetal, 4-aminobutyraldehyde diethyl acetal, 2-methylaminomethyl-1,3-dioxolane, ethanolamine, 3-amino-1-propanol, 2-hydroxyethylhydrazine, N,N-diethylhydroxylamine, 4-amino-1-butanol, 2-(2-aminoethoxy)ethanol, 2-(methylamino)ethanol, 2-(ethylamino)ethanol, 2-(propylamino)ethanol, diethanolamine, diisopropanolamine, N,N-dimethylethanolamine, N,N-diethylethanolamine, 2-(dibutylamino)ethanol, 3-dimethylamino-1-propanol, 3-diethylamino-1-propanol, 1-dimethylamino-2-propanol, 1-diethylamino-2-propanol, N-methyldiethanolamine, N-ethyldiethanolamine, 3-amino-1,2-propanediol, and mixtures thereof.

Thiols.

Suitable thiol solvents include 1-propanethiol, 1-butanethiol, 2-butanethiol, 2-methyl-1-propanethiol, t-butyl thiol, 1-pentanethiol, 3-methyl-1-butanethiol, cyclopentanethiol, 1-hexanethiol, cyclohexanethiol, 1-heptanethiol, 1-octanethiol, 2-ethyhexanethiol, 1-nonanethiol, tert-nonyl mercaptan, 1-decanethiol, mercaptoethanol, 4-cyano-1-butanethiol, butyl 3-mercaptoproprionate, methyl 3-mercaptoproprionate, 1-mercapto-2-propanol, 3-mercapto-1-propanol, 4-mercapto-1-butanol, 6-mercapto-1-hexanol, 2-phenylethanethiol, and thiophenol.

Molecular Precursor Preparation.

Preparing the molecular precursor typically comprises mixing the components (i)-(iv) by any conventional method. If one or more of the copper-, tin-, zinc-, or chalcogen sources is a liquid at room temperature or at the processing temperatures, the use of a separate solvent is optional. Otherwise, a solvent is used. In some embodiments, the molecular precursor is a solution; in other embodiments, the molecular precursor is a suspension or dispersion. Typically, the preparation is conducted under an inert atmosphere, taking precautions to protect the reaction mixtures from air and light.

In some embodiments, the molecular precursor is prepared at low temperatures and/or with slow additions, e.g., when larger amounts of reagents and/or low boiling point and/or highly reactive reagents such as CS₂ and ZnEt₂ are utilized. In such cases, the ink is typically stirred at room temperature prior to heat processing. In some embodiments, the molecular precursor is prepared at about 20-100° C., e.g., when smaller amounts of reagents are used, the reagents are solids or have high boiling points and/or when one or more of the solvents is a solid at room temperature, e.g., 2-aminopyridine or 3-aminopyridine. In some embodiments, all of the ink components are added together at room temperature, e.g., when smaller amounts of reagents are used. In some embodiments, elemental chalcogen is added last, following the mixing of all the other components for about half an hour at room temperature. In some embodiments, the components are added consecutively. For example, all of the reagents except copper can be mixed and heated at about 100° C. prior to addition of the copper source, or all of the reagents except tin can be mixed and heated at about 100° C. prior to the addition of the tin source. In some embodiments, each of the copper, zinc and tin sources is dissolved or suspended in a portion of the vehicle, and the components are added consecutively with slow addition and/or with one or more of the component/vehicle mixtures cooled to below room temperature. For example, a solution of the tin source can be added slowly to a suspension of the copper source and the resulting mixture heated at 100° C. for 24 h. Next, a solution of the zinc compound can be added dropwise to the copper/tin/vehicle mixture with stirring, followed by additional heating.

Heat-Processing of the Molecular Precursor.

In some embodiments, the molecular precursor is heat-processed at a temperature of greater than about 90° C., 100° C., 110° C., 120° C., 130° C., 140° C., 150 C.°, 160° C., 170° C., 180° C. or 190° C. before coating on the substrate. Suitable heating methods include conventional heating and micowave heating. In some embodiments, it has been found that this heat-processing step aids the formation of CZTS-Se from the molecular precursor. XAS analysis of films formed from heat-processed molecular precursors indicate the presence of kesterite upon heating the films at temperatures as low as 120° C. This optional heat-processing step is typically carried out under an inert atmosphere. The molecular precursor produced at this stage can be stored for extended periods (e.g., months) without any noticeable decrease in efficacy.

Mixtures of Molecular Precursors.

In some embodiments two or more molecular precursors are prepared separately, with each molecular precursor comprising a complete set of reagents, e.g., each molecular precursor comprises at least a zinc source, a copper source, a tin source and a vehicle. The two or more molecular precursors can then be combined following mixing or following heat-processing. This method is especially useful for controlling stoichiometry and obtaining CTS-Se or CZTS-Se of high purity, as prior to combining, separate films from each molecular precursor can be coated, annealed, and analyzed by XRD. The XRD results can guide the selection of the type and amount of each molecular precursor to be combined. For example, a molecular precursor yielding an annealed film of CZTS-Se with traces of copper sulfide and zinc sulfide can be combined with a molecular precursor yielding an annealed film of CZTS-Se with traces of tin sulfide, to form a molecular precursor that yields an annealed film comprising only CZTS-Se, as determined by XRD.

### Plurality of Particles.

Molar Ratios of the Plurality of Particles.

In some embodiments, the molar ratio of Cu:Zn:Sn is about 2:1:1 in the plurality of particles. In some embodiments, the molar ratio of Cu to (Zn+Sn) is less than one in the plurality of particles. In some embodiments, the molar ratio of Zn to Sn is greater than one in the plurality of particles. In some embodiments, the ratio of Cu, Zn, and Sn can deviate from a 2:1:1 molar ratio by +/−40 mole %, +/−30 mole %, +/−20 mole %, +/−10 mole %, or +/−5 mole %.

In some embodiments, the molar ratio of total chalcogen to (Cu+Zn+Sn) is at least about 1 in the plurality of particles, and is determined as defined above for the ink.

Particles.

The particles can be purchased or synthesized by known techniques such milling and sieving of bulk quantities of the material. In some embodiments, the particles have an average longest dimension of less than about 5 microns, 4 microns, 3 microns, 2 microns, 1.5 microns, 1.25 microns, 1.0 micron, or 0.75 micron.

Microparticles.

In some embodiments the particles comprise microparticles. The microparticles have an average longest dimension of at least about 0.5, 0.6, 0.7, 0.8, 0.9, 1.0, 1.1, 1.2, 1.3, 1.4, 1.5, 1.6, 1.7, 1.8, 1.9, 2.0, 3.0, 4.0, 5.0, 7.5, 10, 15, 20, 25, 50, 75, 100, 125, 150, 175, or 200 microns.

In embodiments in which in which the average longest dimension of the microparticles is less than the average thickness of the coated and/or annealed absorber layer, useful size ranges for microparticles are at least about 0.5 to about 10 microns, 0.6 to 5 microns, 0.6 to 3 microns, 0.6 to 2 microns, 0.6 to 1.5 microns, 0.6 to 1.2 microns, 0.8 to 2 microns, 1.0 to 3.0 microns, 1.0 to 2.0 microns, or 0.8 to 1.5 microns. In embodiments in which the average longest dimension of the microparticles is longer than the average thickness of the coated and/or annealed absorber layer, useful size ranges for microparticles are at least about 1 to about 200 microns, 2 to 200 microns, 2 to 100 microns, 3 to 100 microns, 2 to 50 microns, 2 to 25 microns, 2 to 20 microns, 2 to 15 microns, 2 to 10 microns, 2 to 5 microns, 4 to 50 microns, 4 to 25 microns, 4 to 20, 4 to 15, 4 to 10 microns, 6 to 50 microns, 6 to 25 microns, 6 to 20 microns, 6 to 15 microns, 6 to 10 microns, 10 to 50 microns, 10 to 25 microns, or 10 to 20 microns. The average thickness of the coated and/or annealed absorber layer can be determined by profilometry. The average longest dimension of the microparticles can be determined by electron microscopy.

Nanoparticles.

In some embodiments, the particles comprise nanoparticles. The nanoparticles can have an average longest dimension of less than about 500 nm, 400 nm, 300 nm, 250 nm, 200 nm, 150 nm, or 100 nm, as determined by electron microscopy. The nanoparticles can be purchased or synthesized by known techniques, such as: decomposition and reduction of metal salts and complexes; chemical vapor deposition; electrochemical deposition; use of gamma-, x-ray, laser or UV-irradiation; ultrasonic or microwave treatment; electron- or ion-beams; arc discharge; electric explosion of wires; or biosynthesis.

Capping Agent.

In some embodiments, the particles further comprise a capping agent. The capping agent can aid in the dispersion of particles and can also inhibit their interaction and agglomeration in the ink.

In some embodiments, the capping agent comprises a surfactant or a dispersant. Suitable capping agents include:

(a) Organic molecules that contain functional groups such as N-, O-, S-, Se- or P-based functional groups.

(b) Lewis bases. The Lewis base can be chosen such that it has a boiling temperature at ambient pressure that is greater than or equal to about 200° C., 150° C., 120° C., or 100° C. and/or can be selected from the group consisting of: organic amines, phosphine oxides, phosphines, thiols, selenols, and mixtures thereof.

(c) Amines, thiols, selenols, phosphine oxides, phosphines, phosphinic acids, pyrrolidones, pyridines, carboxylates, phosphates, heteroaromatics, peptides, and alcohols.

(d) Alkyl amines, alkyl thiols, alkyl selenols, trialkylphosphine oxide, trialkylphosphines, alkylphosphonic acids, polyvinylpyrrolidone, polycarboxylates, polyphosphates, polyamines, pyridine, alkylpyridines, aminopyridines, peptides comprising cysteine and/or histidine residues, ethanolamines, citrates, thioglycolic acid, oleic acid, and polyethylene glycol.

(e) Inorganic chalcogenides, including metal chalcogenides, and zintl ions.

(f) S²⁻, Se²⁻, Se₂²⁻, Se₃²⁻, Se₄²⁻, Se₆²⁻, Te₂²⁻, Te₃²⁻, Te₄²⁻, Sn₄²⁻, Sn₅²⁻, Sn₉³⁻, Sn₉⁴⁻, SnS₄⁴⁻, SnTe₄⁴⁻, Sn₂S₆⁴⁻, Sn₂Se₆⁴⁻, Sn₂Te₆⁴⁻, wherein the positively charged counterions can be alkali metal ions, ammonium, hydrazinium, or tetraalkylammonium.

(g) Degradable capping agents, including dichalcogenocarbamates, monochalcogenocarbamates, xanthates, trithiocarbonates, dichalcogenoimidodiphosphates, thiobiurets, dithiobiurets, chalcogenosemicarbazides, and tetrazoles. In some embodiments, the capping agents can be degraded either by thermal and/or chemical processes, such as acid- and base-catalyzed processes. Degradable capping agents include: dialkyl dithiocarbamates, dialkyl monothiocarbamates, dialkyl diselenocarbamates, dialkyl monoselenocarbamates, alkyl xanthates, alkyl trithiocarbonates, disulfidoimidodiphosphates, diselenoimidodiphosphates, tetraalkyl thiobiurets, tetraalkyl dithiobiurets, thiosemicarbazides, selenosemicarbazides, tetrazole, alkyl tetrazoles, amino-tetrazoles, thio-tetrazoles, and carboxylated tetrazoles. In some embodiments, Lewis bases can be added to nanoparticles stabilized by carbamate, xanthate, or trithiocarbonate capping agents to catalyze their removal from the nanoparticle. The Lewis bases can comprise an amine.

(h) Molecular precursor complexes to copper chalcogenides, zinc chalcogenides, and tin chalcogenides. Suitable ligands for these molecular precursor complexes include: thio groups, seleno groups, thiolates, selenolates, and thermally degradable capping agents, as described above. Suitable thiolates and selenolates include: alkyl thiolates, alkyl selenolates, aryl thiolates, and aryl selenolates.

(i) Molecular precursor complexes to CuS/Se, Cu₂S/Se, ZnS/Se, SnS/Se, Sn(S/Se)₂, Cu₂Sn(S/Se)₃, Cu₂ZnSn(S/Se)₄. Particularly suitable capping agents for CZTS/Se particles include the molecular precursor inks to CZTS/Se described above.

(j) The solvent in which the particle is formed, such as oleylamine.

(k) Short-chain carboxylic acids, including formic, acetic, and oxalic acid.

Volatile Capping Agents.

In some embodiments, the particles comprise a volatile capping agent. A capping agent is considered volatile if, instead of decomposing and introducing impurities when a composition or ink of nanoparticles is formed into a film, it evaporates during film deposition, drying or annealing. Volatile capping agents include those having a boiling point less than about 200° C., 150° C., 120° C., or 100° C. at ambient pressure. Volatile capping agents can be adsorbed or bonded onto particles during synthesis or during an exchange reaction. Thus, in one embodiment, particles, or an ink or reaction mixture of particles stabilized by a first capping agent, as incorporated during synthesis, are mixed with a second capping agent that has greater volatility to exchange in the particles the second capping agent for the first capping agent. Suitable volatile capping agents include: ammonia, methyl amine, ethyl amine, butylamine, tetramethylethylene diamine, acetonitrile, ethyl acetate, butanol, pyridine, ethanethiol, propanethiol, butanethiol, t-butylthiol, pentanethiol, hexanethiol, tetrahydrofuran, and diethyl ether. Suitable volatile capping agents can also include: amines, amidos, amides, nitriles, isonitriles, cyanates, isocyanates, thiocyanates, isothiocyanates, azides, thiocarbonyls, thiols, thiolates, sulfides, sulfinates, sulfonates, phosphates, phosphines, phosphites, hydroxyls, hydroxides, alcohols, alcoholates, phenols, phenolates, ethers, carbonyls, carboxylates, carboxylic acids, carboxylic acid anhydrides, glycidyls, and mixtures thereof.

Elemental Particles.

In some embodiments, the plurality of particles comprises elemental Cu-, elemental Zn- or elemental Sn-containing particles. In some embodiments, the plurality of particles consists essentially of elemental Cu-, elemental Zn- or elemental Sn-containing particles. Suitable elemental Cu-containing particles include: Cu particles, Cu—Sn alloy particles, Cu—Zn alloy particles, and mixtures thereof. Suitable elemental Zn-containing particles include: Zn particles, Cu—Zn alloy particles, Zn—Sn alloy particles, and mixtures thereof. Suitable elemental Sn-containing particles include: Sn particles, Cu—Sn alloy particles, Zn—Sn alloy particles, and mixtures thereof. In some embodiments, the elemental Cu-, elemental Zn- or elemental Sn-containing particles are nanoparticles. The elemental Cu-, elemental Zn- or elemental Sn-containing nanoparticles can be obtained from Sigma-Aldrich (St. Louis, Mo.), Nanostructured and Amorphous Materials, Inc. (Houston, Tex.), American Elements (Los Angeles, Calif.), Inframat Advanced Materials LLC (Manchester, Conn.), Xuzhou Jiechuang New Material Technology Co., Ltd. (Guangdong, China), Absolute Co. Ltd. (Volgograd, Russian Federation), MTI Corporation (Richmond, Va.), or Reade Advanced Materials (Providence, R.I.). Elemental Cu-, Zn- or Sn-containing nanoparticles can also be synthesized according to known techniques, as described above. In some instances, the elemental Cu-, elemental Zn- or elemental Sn-containing particles may comprise a capping agent.

Binary or Ternary Chalcogenide Particles.

In some embodiments, the plurality of particles comprises binary or ternary Cu-, Zn- or Sn-containing chalcogenide particles. In some embodiments, the plurality of particles consists essentially of binary or ternary Cu-, Zn- or Sn-containing chalcogenide particles; and mixtures thereof. In some embodiments, the chalcogenide is a sulfide or selenide. Suitable Cu-containing binary or ternary chalcogenide particles include: Cu₂S/Se particles, CuS/Se particles, Cu₂Sn(S/Se)₃ particles, Cu₄Sn(S/Se)₄ particles, and mixtures thereof. Suitable Zn-containing binary chalcogenide particles include ZnS/Se particles. Suitable Sn-containing binary or ternary chalcogenide particles include: Sn(S/Se)₂ particles, SnS/Se particles, Cu₂Sn(S/Se)₃ particles, Cu₄Sn(S/Se)₄ particles, and mixtures thereof. In some embodiments, the binary or ternary Cu-, Zn- or Sn-containing chalcogenide nanoparticles can be purchased from Reade Advanced Materials (Providence, R.I.) or synthesized according to known techniques. A particularly useful aqueous method for synthesizing mixtures of copper-, zinc- and tin-containing chalcogenide nanoparticles follows:
(a) providing a first aqueous solution comprising two or more metal salts and one or more ligands;
(b) optionally, adding a pH-modifying substance to form a second aqueous solution;
(c) combining the first or second aqueous solution with a chalcogen source to provide a reaction mixture; and
(d) agitating and optionally heating the reaction mixture to produce metal chalcogenide nanoparticles.

In one embodiment, the process further comprises separating the metal chalcogenide nanoparticles from the reaction mixture. In another embodiment, the process further comprises cleaning the surface of the nanoparticles. In another embodiment, the process further comprises reacting the surface of the nanoparticles with capping groups.

CZTS/Se Particles.

In some embodiments, the plurality of particles comprises CZTS/Se particles. In some embodiments, the plurality of particles consists essentially of CZTS/Se particles.

CZTS/Se Nanoparticles.

In some embodiments, the CZTS/Se particles comprise CZTS/Se nanoparticles. In some embodiments, the CZTS/Se particles consist essentially of CZTS/Se nanoparticles. The CZTS/Se nanoparticles can be synthesized by methods known in the art, as described above. A particularly useful aqueous method for synthesizing CZTS/Se nanoparticles comprises steps (a)-(d) as described above in the aqueous method for synthesizing mixtures of copper-, zinc- and tin-containing chalcogenide nanoparticles, followed by steps (e) and (f):
(e) separating the metal chalcogenide nanoparticles from reaction by-products; and
(f) heating the metal chalcogenide nanoparticles to provide crystalline multinary-metal chalcogenide particles.

The annealing time can be used to control the CZTS/Se particle size, with particles ranging from nanoparticles to microparticles, as annealing time lengthens.

Capped Nanoparticles.

In some instances, the nanoparticles comprise a capping agent. Particularly useful methods for synthesizing coated copper-, zinc- or tin-containing chalcogenide nanoparticles follow:

Coated binary, ternary, and quaternary chalcogenide nanoparticles, including CuS, CuSe, ZnS, ZnSe, SnS, Cu₂SnS₃, and Cu₂ZnSnS₄, can be prepared from corresponding metal salts or complexes by reaction of the metal salt or complex with a source of sulfide or selenide in the presence of one or more stabilizing agents at a temperature between 0° C. and 500° C., or between 150° C. and 350° C. In some circumstances, the stabilizing agent also provides the coating. The chalcogenide nanoparticles can be isolated, for example, by precipitation by a non-solvent followed by centrifugation, and can be further purified by washing, or dissolving and re-precipitating. Suitable metal salts and complexes for this synthetic route include Cu(I), Cu(II), Zn(II), Sn(II) and Sn(IV) halides, acetates, nitrates, and 2,4-pentanedionates. Suitable chalcogen sources include elemental sulfur, elemental selenium, Na₂S, Na₂Se, (NH₄)₂S, (NH₄)₂Se, thiourea, and thioacetamide. Suitable stabilizing agents include the capping agents disclosed above. In particular, suitable stabilizing agents include: dodecylamine, tetradecyl amine, hexadecyl amine, octadecyl amine, oleylamine, trioctyl amine, trioctylphosphine oxide, other trialkylphosphine oxides, and trialkylphosphines.

Cu₂S nanoparticles can be synthesized by a solvothermal process, in which the metal salt is dissolved in deionized water. A long-chain alkyl thiol or selenol (e.g., 1-dodecanethiol or 1-dodecaneselenol) can serve as both the sulfur (or selenium) source and a dispersant for nanoparticles. Some additional ligands, including acetate and chloride, can be added in the form of an acid or a salt. The reaction is typically conducted at a temperature between 150° C. and 300° C. and at a pressure between 150 psig and 250 psig nitrogen. After cooling, the product can be isolated from the non-aqueous phase, for example, by precipitation using a non-solvent and filtration.

The chalcogenide nanoparticles can also be synthesized by an alternative solvothermal process in which the corresponding metal salt is dispersed along with thioacetamide, thiourea, selenoacetamide, selenourea or other source of sulfide or selenide ions and an organic stabilizing agent (e.g., a long-chain alkyl thiol or a long-chain alkyl amine) in a suitable solvent at a temperature between 150° C. and 300° C. The reaction is typically conducted at a pressure between 150 psig nitrogen and 250 psig nitrogen. Suitable metal salts for this synthetic route include Cu(I), Cu(II), Zn(II), Sn(II) and Sn(IV) halides, acetates, nitrates, and 2,4-pentanedionates.

The resultant chalcogenide nanoparticles obtained from any of the three routes are coated with the organic stabilizing agent(s), as can be determined by secondary ion mass spectrometry and nuclear magnetic resonance spectroscopy. The structure of the inorganic crystalline core of the coated nanoparticles obtained can be determined by X-ray diffraction (XRD) and transmission electron microscopy (TEM) techniques.

CZTS/Se Microparticles.

In some embodiments, the CZTS/Se particles comprise CZTS/Se microparticles. In some embodiments, the CZTS/Se particles consist essentially of CZTS/Se microparticles. The CZTS/Se microparticles can be synthesized by methods known in the art, such as by heating a mixture of Cu, Zn and Sn sulfides together in a furnace at high temperatures. A particularly useful method for the synthesis of CZTS/Se microparticles involves reacting ground Cu-, Zn- and Sn-containing binary and/or ternary chalcogenides together in a molten flux in an isothermal recrystallization process. The crystal size of the materials can be controlled by the temperature and duration of the recrystallization process and by the chemical nature of the flux. The aqueous method described above is another particularly useful method for synthesizing CZTS/Se microparticles.

In some instances, the microparticles synthesized via these methods might be larger than desired. In such cases, the CZTS/Se microparticles can be milled or sieved using standard techniques to achieve the desired particle size.

In some instances, the CZTS/Se microparticles comprise a capping agent. The coated CZTS/Se microparticles can be synthesized by standard techniques known in the art, such as mixing the microparticle with a liquid capping agent, optionally with heating, and then washing the coated particles to remove excess capping agent. CZTS/Se microparticles capped with CZTS/Se molecular precursors can be synthesized by mixing CZTS/Se microparticles with the CZTS/Se molecular precursor ink described above. In some embodiments, the mixture is heat-processed at a temperature of greater than about 50° C., 75° C., 90° C., 100° C., 110° C., 120° C., 130° C., 140° C., 150 C.°, 160° C., 170° C., 180° C. or 190° C. Suitable heating methods include conventional heating and micowave heating. In some embodiments, the CZTS/Se microparticles are mixed with a molecular precursor ink wherein solvent(s) comprises less than about 90 wt %, 80 wt %, 70 wt %, 60 wt %, or 50 wt % of the ink, based upon the total weight of the ink. Following mixing and optional heating, the CZTS/Se microparticles are washed with solvent to remove excess molecular precursor. Suitable solvents for washing can be selected from the above list of solvents for the molecular precursor.

### Additional Ink Components

In addition to the molecular precursor and the plurality of particles, the ink can further comprise additives, an elemental chalcogen, or mixtures thereof.

Additives.

In some embodiments, the ink further comprises one or more additives. Suitable additives include dispersants, surfactants, polymers, binders, ligands, capping agents, defoamers, dispersants, thickening agents, corrosion inhibitors, plasticizers, thixotropic agents, viscosity modifiers, and dopants. In some embodiments, additives are selected from the group consisting of: capping agents, dopants, polymers, and surfactants. In some embodiments, the ink comprises up to about 10 wt %, 7.5 wt %, 5 wt %, 2.5 wt % or 1 wt % additives, based upon the total weight of the ink. Suitable capping agents comprise the capping agents, including volatile capping agents, described above.

Dopants.

Suitable dopants include sodium and alkali-containing compounds selected from the group consisting of: alkali compounds comprising N-, O-, C-, S-, or Se-based organic ligands, alkali sulfides, alkali selenides, and mixtures thereof. In other embodiments, the dopant comprises an alkali-containing compound selected from the group consisting of: alkali-compounds comprising amidos; alkoxides; acetylacetonates; carboxylates; hydrocarbyls; O-, N-, S-, Se-, halogen-, and tri(hydrocarbyl)silyl-substituted hydrocarbyls; thio- and selenolates; thiO-, selenO-, and dithiocarboxylates; dithiO-, diselenO-, and thioselenocarbamates; and dithioxanthogenates. Other suitable dopants include antimony chalcogenides selected from the group consisting of: antimony sulfide and antimony selenide.

Polymers and Surfactants.

Suitable polymeric additives include vinylpyrrolidone-vinylacetate copolymers and (meth)acrylate copolymers, including PVP/VA E-535 (International Specialty Products), and Elvacite® 2028 binder and Elvacite® 2008 binder (Lucite International, Inc.). In some embodiments, polymers can function as binders or dispersants.

Suitable surfactants include siloxy-, fluoryl-, alkyl-, alkynyl-, and ammonium-substituted surfactants. These include, for example, Byk® surfactants (Byk Chemie), Zonyl® surfactants (DuPont), Triton® surfactants (Dow), Surfynol® surfactants (Air Products), Dynol® surfactants (Air Products), and Tego® surfactants (Evonik Industries AG). In certain embodiments, surfactants may function as coating aids, capping agents, or dispersants.

In some embodiments, the ink comprises one or more binders or surfactants selected from the group consisting of: decomposable binders; decomposable surfactants; cleavable surfactants; surfactants with a boiling point less than about 250° C.; and mixtures thereof. Suitable decomposable binders include: homo- and co-polymers of polyethers; homo- and co-polymers of polylactides; homo- and co-polymers of polycarbonates including, for example, Novomer PPC (Novomer, Inc.); homo- and co-polymers of poly[3-hydroxybutyric acid]; homo- and co-polymers of polymethacrylates; and mixtures thereof. A suitable low boiling surfactant is Surfynol® 61 surfactant from Air Products. Cleavable surfactants useful herein as capping agents include Diels-Alder adducts, thiirane oxides, sulfones, acetals, ketals, carbonates, and ortho esters. Suitable cleavable surfactants include: alkyl-substituted Diels Alder adducts, Diels Alder adducts of furans; thiirane oxide; alkyl thiirane oxides; aryl thiirane oxides; piperylene sulfone, butadiene sulfone, isoprene sulfone, 2,5-dihydro-3-thiophene carboxylic acid-1,1-dioxide-alkyl esters, alkyl acetals, alkyl ketals, alkyl 1,3-dioxolanes, alkyl 1,3-dioxanes, hydroxylacetals, alkyl glucosides, ether acetals, polyoxyethylene acetals, alkyl carbonates, ether carbonates, polyoxyethylene carbonates, ortho esters of formates, alkyl ortho esters, ether ortho esters, and polyoxyethylene ortho esters.

Elemental Chalcogen.

In some embodiments, the ink comprises an elemental chalcogen selected from the group consisting of sulfur, selenium, and mixtures thereof. Useful forms of sulfur and selenium include powders that can be obtained commercially from Sigma-Aldrich (St. Louis, Mo.) and Alfa Aesar (Ward Hill, Mass.). In some embodiments, the chalcogen powder is soluble in the ink vehicle. If the chalcogen is not soluble in the vehicle, its particle size can be 1 nm to 200 microns. In some embodiments, the particles have an average longest dimension of less than about 100 microns, 50 microns, 25 microns, 10 microns, 5 microns, 4 microns, 3 microns, 2 microns, 1.5 microns, 1.25 microns, 1.0 micron, 0.75 micron, 0.5 micron, 0.25 micron, or 0.1 micron. Preferably, the chalcogen particles are smaller than the thickness of the film that is to be formed. The chalcogen particles can be formed by ball milling, evaporation-condensation, melting and spraying (“atomization”) to form droplets, or emulsification to form colloids.

Ink Preparation.

Typically, ink preparation is conducted under an inert atmosphere, taking precautions to protect the reaction mixtures from air and light. Preparing an ink comprises mixing a molecular precursor with a plurality of particles by any conventional method. Typically, the molecular precursor portion of the ink is prepared as described above with components (i)-(iv) added and mixed, often with heat processing, prior to the addition of the particles. Then the plurality of particles is added to the molecular precursor at room temperature, followed by mixing, and, optionally, heat treatment. Depending on the relative amounts of the molecular precursor and plurality of particles, it can be necessary to add solvent to the ink to adjust the viscosity. The solvent can be added before or after heat treatment. In some embodiments, suitable solvents are as described above for the preparation of the molecular precursor. In some embodiments, the wt % of the plurality of particles in the ink, based upon the weight of the final ink, ranges from about 95 to about 5 wt %, 90 to 10 wt %, 80 to 20 wt %, 70 to 30 wt %, or 60 to 40 wt %. In some embodiments, particularly those wherein the plurality of particles comprises microparticles, the wt % of the particles in the ink, based upon the weight of the final ink, is less than about 90 wt %, 80 wt %, 70 wt %, 60 wt %, 50 wt %, 40 wt %, 30 wt %, 20 wt %, 10 wt %, or 5 wt %.

Typically, the plurality of particles is added as a dry solid to the molecular precursor. In some embodiments, the plurality of particles can be added as a dispersion in a second vehicle to the molecular precursor. In some embodiments, the second vehicle is selected from the group consisting of: fluids and low melting solids, wherein the melting point of the low-melting solid is less than about 100° C., 90° C., 80° C., 70° C., 60° C., 50° C., 40° C., or 30° C. In some embodiments, the second vehicle comprises solvents. The solvents can be selected from the lists above. Suitable solvents also include aromatics, heteroaromatics, alkanes, chlorinated alkanes, ketones, esters, nitriles, amides, amines, thiols, pyrrolidinones, ethers, thioethers, alcohols, and mixtures thereof. In some embodiments, the wt % of the second vehicle in the dispersion of particles that is added to the molecular precursor is about 95 to about 5 wt %, 90 to 10 wt %, 80 to 20 wt %, 70 to 30 wt %, or 60 to 40 wt %, based upon the total weight of the dispersion. In some embodiments, the second vehicle can function as a dispersant or capping agent, as well as being the carrier vehicle for the particles. Solvent-based second vehicles that are particularly useful as capping agents comprise heteroaromatics, amines, and thiols.

In some embodiments, particularly those in which the average longest dimension of the microparticles is longer than the desired average thickness of the coated and/or annealed absorber layer, the ink is prepared on a substrate. Suitable substrates for this purpose are as described below. For example, the molecular precursor can be deposited on the substrate, with suitable deposition techniques as described below. Then the plurality of particles can be added to the molecular precursor by techniques such as sprinkling the plurality of the particles onto the deposited molecular precursor.

Heat-Processing of the Ink.

In some embodiments, the ink is heat-processed at a temperature of greater than about 100° C., 110° C., 120° C., 130° C., 140° C., 150 C.°, 160° C., 170° C., 180° C., or 190° C. before coating on the substrate. Suitable heating methods include conventional heating and micowave heating. In some embodiments, it has been found that this heat-processing step aids the dispersion of the plurality of particles within the molecular precursor. Films made from heat-processed inks typically have smooth surfaces, an even distribution of particles within the film as observed by SEM, and improved performance in photovoltaic devices as compared to inks of the same composition that were not heat-processed. This optional heat-processing step is typically carried out under an inert atmosphere. The ink produced at this stage can be stored for months without any noticeable decrease in efficacy.

Mixtures of Inks.

As described above for the mixture of molecular precursors, in some embodiments two or more inks are prepared separately, with each ink comprising a molecular precursor and a plurality of particles. The two or more inks can then be combined following mixing or following heat-processing. This method is especially useful for controlling stoichiometry and obtaining CTS-Se or CZTS-Se of high purity. In other embodiments, an ink comprising a complete set of reagents is combined with ink(s) comprising a partial set of reagents, e.g., a second ink comprises a tin source. As an example, an ink containing only a tin source can be added in varying amounts to an ink comprising a complete set of reagents, and the stoichiometry can be optimized based upon the resulting device performances of annealed films of the mixtures.

### Coated Substrate

Another aspect of this invention is a coated substrate comprising:

A) a substrate; and
B) at least one layer disposed on the substrate comprising:
1) a molecular precursor to CZTS/Se, comprising:
   a) a copper source selected from the group consisting of copper complexes of N-, O-, C-, S-, and Se-based organic ligands, copper sulfides, copper selenides, and mixtures thereof;
   b) a tin source selected from the group consisting of tin complexes of N-, O-, C-, S-, and Se-based organic ligands, tin hydrides, tin sulfides, tin selenides, and mixtures thereof;
   c) a zinc source selected from the group consisting of zinc complexes of N-, O-, C-, S-, and Se-based organic ligands, zinc sulfides, zinc selenides, and mixtures thereof; and
   d) optionally a vehicle, comprising a liquid chalcogen compound, a liquid tin source, a solvent, or a mixture thereof; and
2) a plurality of particles selected from the group consisting of: CZTS/Se particles; elemental Cu-, elemental Zn- or elemental Sn-containing particles; binary or ternary Cu-, Zn- or Sn-containing chalcogenide particles; and mixtures thereof.

Descriptions and preferences regarding the molecular precursor and plurality of particles are the same as described above for the ink composition. In some embodiments, the coated substrate further comprises one or more additional layers.

Another aspect of this invention is a coated substrate comprising:

a) a substrate; and
b) at least one layer comprising:
i) an inorganic matrix; and
ii) CZTS/Se microparticles characterized by an average longest dimension of 0.5-200 microns, wherein the microparticles are embedded in the inorganic matrix.

In the coated substrate, the inorganic matrix comprises inorganic semiconductors, precursors to inorganic semiconductors, inorganic insulators, precursors to inorganic insulators, or mixtures thereof. In some embodiments, the matrix comprises at least 50 wt %, 60 wt %, 70 wt %, 80 wt %, 90 wt %, 95 wt %, or 98 wt %, or consists essentially of inorganic semiconductors, inorganic insulators, precursors to inorganic insulators, or mixtures thereof. Materials designated as inorganic matrixes can also contain small amounts of other materials, including dopants such as sodium, and organic materials. Suitable inorganic matrixes comprise Group IV elemental or compound semiconductors, Group III-V, II-VI, I-VII, IV-VI, V-VI, or II-V semiconductors, oxides, sulfides, nitrides, phosphides, selenides, carbides, antimonides, arsenides, selenides, tellurides, or silicides; precursors thereof; or mixtures thereof. Examples of suitable inorganic matrixes include Cu₂ZnSn(S,Se)₄, Cu(In,Ga)(S,Se)₂, and SiO₂.

Preparation of the Inorganic Matrix.

Inorganic matrixes can be prepared by standard methods known in the art for preparing inorganic semiconductors, inorganic insulators, and precursors thereof and can be combined with microparticles by procedures analogous to those described above. As examples, an inorganic matrix comprising SiO₂ or precursors thereof can be prepared from sol gel precursors to SiO₂; an inorganic matrix comprising Cu₂ZnSn(S,Se)₄ or precursors thereof can be prepared as described above using molecular precursors; and an inorganic matrix comprising Cu(In,Ga)(S,Se)₂ or precursors thereof can be prepared from an ink comprising a molecular precursor to CIGS/Se, comprising:
i) a copper source selected from the group consisting of copper complexes of nitrogen-, oxygen-, carbon-, sulfur-, and selenium-based organic ligands, copper sulfides, copper selenides, and mixtures thereof;
ii) an indium source selected from the group consisting of indium complexes of nitrogen-, oxygen-, carbon-, sulfur-, and selenium-based organic ligands, indium sulfides, indium selenides, and mixtures thereof;
iii) optionally, a gallium source selected from the group consisting of gallium complexes of nitrogen-, oxygen-, carbon-, sulfur-, and selenium-based organic ligands, gallium sulfides, gallium selenides, and mixtures thereof; and
iv) a vehicle, comprising a liquid chalcogen compound, a solvent, or a mixture thereof.

The nitrogen-, oxygen-, carbon-, sulfur-, and selenium-based organic ligands can be selected from the lists given above. In some embodiments, the molecular precursor to Cu(In,Ga)(S,Se)₂ further comprises a chalcogen compound selected from the lists given above.

Another aspect of this invention is a process comprising disposing an ink onto a substrate to form a coated substrate, wherein the ink comprises:

a) a molecular precursor to CZTS/Se, comprising:
i) a copper source selected from the group consisting of copper complexes of N-, O-, C-, S-, and Se-based organic ligands, copper sulfides, copper selenides, and mixtures thereof;
ii) a tin source selected from the group consisting of tin complexes of N-, O-, C-, S-, and Se-based organic ligands, tin hydrides, tin sulfides, tin selenides, and mixtures thereof;
iii) a zinc source selected from the group consisting of zinc complexes of N-, O-, C-, S-, and Se-based organic ligands, zinc sulfides, zinc selenides, and mixtures thereof; and
iv) a vehicle, comprising a liquid chalcogen compound, a liquid tin source, a solvent, or a mixture thereof; and
   b) a plurality of particles selected from the group consisting of: CZTS/Se particles; elemental Cu-, elemental Zn- or elemental Sn-containing particles; binary or ternary Cu-, Zn- or Sn-containing chalcogenide particles; and mixtures thereof.

Substrate

The substrate can be rigid or flexible. In one embodiment, the substrate comprises: (i) a base; and (ii) optionally, an electrically conductive coating on the base. The base material is selected from the group consisting of glass, metals, ceramics, and polymeric films. Suitable base materials include metal foils, plastics, polymers, metalized plastics, glass, solar glass, low-iron glass, green glass, soda-lime glass, metalized glass, steel, stainless steel, aluminum, ceramics, metal plates, metalized ceramic plates, and metalized polymer plates. In some embodiments, the base material comprises a filled polymer (e.g., a polyimide and an inorganic filler). In some embodiments, the base material comprises a metal (e.g., stainless steel) coated with a thin insulating layer (e.g., alumina).

Suitable electrically conductive coatings include metal conductors, transparent conducting oxides, and organic conductors. Of particular interest are substrates of molybdenum-coated soda-lime glass, molybdenum-coated polyimide films, and molybdenum-coated polyimide films further comprising a thin layer of a sodium compound (e.g., NaF, Na₂S, or Na₂Se).

Ink Deposition.

The ink is disposed on a substrate to provide a coated substrate by solution-based coating or printing techniques, including spin-coating, spray-coating, dip-coating, rod-coating, drop-cast coating, roller coating, slot-die coating, draw-down coating, ink-jet printing, contact printing, gravure printing, flexographic printing, and screen printing. The coating can be dried by evaporation, by applying vacuum, by heating, or by combinations thereof. In some embodiments, the substrate and disposed ink are heated at a temperature from 80-350° C., 100-300° C., 120-250° C., or 150-190° C. to remove at least a portion of the solvent, if present, by-products, and volatile capping agents. The drying step can be a separate, distinct step, or can occur as the substrate and precursor ink are heated in an annealing step.

Coated Substrate.

In some embodiments, the molar ratio of Cu:Zn:Sn in the at least one layer on the coated substrate is about 2:1:1. In other embodiments, the molar ratio of Cu to (Zn+Sn) is less than one. In other embodiments, the molar ratio of Zn:Sn is greater than one.

Coated Substrate Comprising Nanoparticles In some embodiments, the plurality of particles in the at least one layer of the coated substrate comprises or consists essentially of nanoparticles having an average longest dimension of less than about 500 nm, 400 nm, 300 nm, 250 nm, 200 nm, 150 nm, or 100 nm, as determined by electron microscopy. As measured by profilometry, Ra (average roughness) is the arithmetic average deviation of roughness. In some embodiments, the plurality of particles of the coated substrate consists essentially of nanoparticles, and the Ra of the at least one layer is less than about 1 micron, 0.9 micron, 0.8 micron, 0 7 micron, 0.6 micron, 0.5 micron, 0.4 micron or 0.3 micron, as measured by profilometry.

Coated Substrate Comprising CZTS/Se Microparticles

In some embodiments, the particles of the coated substrate comprise or consist essentially of CZTS/Se microparticles. In some embodiments, the plurality of particles of the at least one layer of the coated substrate comprises or consists essentially of CZTS/Se microparticles, and the at least one layer comprises CZTS/Se microparticles embedded in an inorganic matrix. In some embodiments, the matrix comprises inorganic particles and the average longest dimension of the microparticles is longer than the average longest dimension of the inorganic particles. In some embodiments, the inorganic particles comprise CZTS/Se particles; elemental Cu-, elemental Zn- or elemental Sn-containing particles; binary or ternary Cu-, Zn- or Sn-containing particles; and mixtures thereof. In some embodiments, the matrix comprises or consists essentially of CZTS/Se or CZTS/Se particles.

The particle sizes can be determined by techniques such as electron microscopy. In some embodiments, the CZTS/Se microparticles of the coated substrate have an average longest dimension of at least about 0.5, 0.6, 0.7, 0.8, 0.9, 1.0, 1.1, 1.2, 1.3, 1.4, 1.5, 1.6, 1.7, 1.8, 1.9, 2.0, 3.0, 4.0, 5.0, 7.5, 10, 15, 20, 25 or 50 micron(s), and the inorganic particles of the coated substrate have an average longest dimension of less than about 10, 7.5, 5.0, 4.0, 3.0, 2.0, 1.5, 1.0, 0.75, 0.5, 0.4, 0.3, 0.2, or 0.1 micron(s). In some embodiments, the inorganic particles comprise or consist essentially of nanoparticles.

In some embodiments, the difference between the average longest dimension of the CZTS/Se microparticles of the coated substrate and the average thickness of the at least one layer is at least about 0.1, 0.2, 0.3, 0.4, 0.5, 0.75, 1.0, 1.5, 2.0, 2.5, 3.0, 5.0, 10.0, 15.0, 20.0 or 25.0 micron(s). In some embodiments, the average longest dimension of the CZTS/Se microparticles of the coated substrate is less than the average thickness of the at least one layer. In some embodiments, the average longest dimension of the CZTS/Se microparticles of the coated substrate is less than the average thickness of the at least one layer, and the Ra of the at least one layer is less than about 1 micron, 0.9 micron, 0.8 micron, 0.7 micron, 0.6 micron, 0.5 micron, 0.4 micron or 0.3 micron, as measured by profilometry. In some embodiments, the average longest dimension of the CZTS/Se microparticles of the coated substrate is greater than the average thickness of the at least one layer.

Annealing.

In some embodiments, the coated substrate is heated at about 100-800° C., 200-800° C., 250-800° C., 300-800° C., 350-800° C., 400-650° C., 450-600° C., 450-550° C., 450-525° C., 100-700° C., 200-650° C., 300-600° C., 350-575° C., or 350-525° C. In some embodiments, the coated substrate is heated for a time in the range of about 1 min to about 48 hr; 1 min to about 30 min; 10 min to about 10 hr; 15 min to about 5 hr; 20 min to about 3 hr; or, 30 min to about 2 hr. Typically, the annealing comprises thermal processing, rapid thermal processing (RTP), rapid thermal annealing (RTA), pulsed thermal processing (PTP), laser beam exposure, heating via IR lamps, electron beam exposure, pulsed electron beam processing, heating via microwave irradiation, or combinations thereof. Herein, RTP refers to a technology that can be used in place of standard furnaces and involves single-wafer processing, and fast heating and cooling rates. RTA is a subset of RTP, and consists of unique heat treatments for different effects, including activation of dopants, changing substrate interfaces, densifying and changing states of films, repairing damage, and moving dopants. Rapid thermal anneals are performed using either lamp-based heating, a hot chuck, or a hot plate. PTP involves thermally annealing structures at extremely high power densities for periods of very short duration, resulting, for example, in defect reduction. Similarly, pulsed electron beam processing uses a pulsed high energy electron beam with short pulse duration. Pulsed processing is useful for processing thin films on temperature-sensitive substrates. The duration of the pulse is so short that little energy is transferred to the substrate, leaving it undamaged.

In some embodiments, the annealing is carried out under an atmosphere comprising: an inert gas (nitrogen or a Group VIIIA gas, particularly argon); optionally hydrogen; and optionally, a chalcogen source such as selenium vapor, sulfur vapor, hydrogen sulfide, hydrogen selenide, diethyl selenide, or mixtures thereof. The annealing step can be carried out under an atmosphere comprising an inert gas, provided that the molar ratio of total chalcogen to (Cu+Zn+Sn) in the coating is greater than about 1. If the molar ratio of total chalcogen to (Cu+Zn+Sn) is less than about 1, the annealing step is carried out in an atmosphere comprising an inert gas and a chalcogen source. In some embodiments, at least a portion of the chalcogen present in the coating (e.g., S) can be exchanged (e.g., S can be replaced by Se) by conducting the annealing step in the presence of a different chalcogen (e.g., Se). In some embodiments, annealings are conducted under a combination of atmospheres. For example, a first annealing is carried out under an inert atmosphere and a second annealing is carried out in an atmosphere comprising an inert gas and a chalcogen source as described above or vice versa. In some embodiments, the annealing is conducted with slow heating and/or cooling steps, e.g., temperature ramps and declines of less than about 15° C. per min, 10° C. per min, 5° C. per min, 2° C. per min, or 1° C. per min. In other embodiments, the annealing is conducted with rapid and/or cooling steps, e.g., temperature ramps and/or declines of greater than about 15° C. per min, 20° C. per min, 30° C. per min, 45° C. per min, or 60° C. per min.

Additional Layers.

In some embodiments, the coated substrate further comprises one or more additional layers. These one or more layer(s) can be of the same composition as the at least one layer or can differ in composition. In some embodiments, particularly suitable additional layer(s) comprise CZTS/Se precursors selected from the group consisting of: CZTS/Se molecular precursors, CZTS/Se nanoparticles, elemental Cu-, elemental Zn- or elemental Sn-containing nanoparticles; binary or ternary Cu-, Zn- or Sn-containing chalcogenide nanoparticles; and mixtures thereof. In some embodiments, the one or more additional layer(s) are coated on top of the at least one layer. This layered structure is particularly useful when the at least one layer contains microparticles, as the top-coated additional layer(s) can serve to planarize the surface of the at least one layer or fill in voids in the at least one layer. In some embodiments, the one or more additional layer(s) are coated prior to coating the at least one layer. This layered structure is also particularly useful when the at least one layer contains microparticles, as the one or more additional layer(s) serve as underlayers that can improve the adhesion of the at least one layer and prevent any shorts that might result from voids in the at least one layer. In some embodiments, the additional layers are coated both prior to and subsequent to the coating of the at least one layer.

In some embodiments, a soft-bake step and/or annealing step occurs between coating the at least one layer and the one or more additional layer(s).

### Films

Another aspect of this invention is a film comprising:

a) an inorganic matrix; and
b) CZTS/Se microparticles characterized by an average longest dimension of 0.5-200 microns, wherein the microparticles are embedded in the inorganic matrix.

CZTS-Se Composition.

An annealed film comprising CZTS/Se is produced by the above annealing processes. In some embodiments, the coherent domain size of the CZTS-Se film is greater than about 30 nm, 40 nm, 50 nm, 60 nm, 70 nm, 80 nm, 90 nm, or 100 nm, as determined by XRD. In some embodiments, the molar ratio of Cu:Zn:Sn is about 2:1:1 in the annealed film. In other embodiments, the molar ratio of Cu to (Zn+Sn) is less than one, and, in other embodiments, a molar ratio of Zn to Sn is greater than one in an annealed film comprising CZTS-Se.

In some embodiments, the annealed film is produced from a coated substrate wherein the particles of the coated substrate comprise or consist essentially of CZTS/Se microparticles. In some embodiments, the annealed film comprises CZTS/Se microparticles embedded in an inorganic matrix. In some embodiments, the inorganic matrix comprises or consists essentially of CZTS/Se or CZTS/Se particles.

The composition and planar grain sizes of the annealed film, as determined by EDX and electron microscopy measurements, can vary depending on the ink composition, processing, and annealing conditions. According to these methods, in some embodiments, the microparticles are indistiguishable from the grains of the inorganic matrix in terms of size and/or composition, and in other embodiments, the microparticles are distinguishable from the grains of the inorganic matrix in terms of size and/or composition. In some embodiments, the planar grain size of the matrix is at least about 0.1, 0.2, 0.3, 0.4, 0.5, 0.6, 0.7, 0.8, 0.9, 1.0, 1.1, 1.2, 1.3, 1.4, 1.5, 1.6, 1.7, 1.8, 1.9, 2.0, 2.5, 3.0, 3.5, 4.0, 4.5, 5.0, 7.5, 10, 15, 20, 25 or 50 micron(s). In some embodiments, the CZTS/Se microparticles have an average longest dimension of at least about 0.5, 0.6, 0.7, 0.8, 0.9, 1.0, 1.1, 1.2, 1.3, 1.4, 1.5, 1.6, 1.7, 1.8, 1.9, 2.0, 3.0, 3.5, 4.0, 5.0, 7.5, 10, 15, 20, 25 or 50 micron(s). In some embodiments, the difference between the average longest dimension of the CZTS/Se microparticles and the planar grain size of the inorganic matrix is at least about 0.1, 0.2, 0.3, 0.4, 0.5, 0.75, 1.0, 1.5, 2.0, 2.5, 3.0, 5.0, 7.5, 10.0, 15.0, 20.0 or 25.0 micron(s). In various embodiments, the average longest dimension of the microparticles is less than, greater than, or equivalent to the planar grain size of the inorganic matrix.

In various embodiments in which both the CZTS/Se microparticles and the inorganic matrix consist essentially of CZTS/Se, there can be differences in the composition of the CZTS/Se microparticles and the inorganic matrix. The differences can be due to differences in one or more of: (a) the fraction of chalcogenide present as sulfur or selenium in the CZTS/Se, (b) the molar ratio of Cu to (Zn+Sn); (c) the molar ratio of Zn to Sn; (d) the molar ratio of total chalcogen to (Cu+Zn+Sn); (e) the amount and type of dopants; and (e) the amount and type of trace impurities. In some embodiments, the composition of the matrix is given by Cu₂ZnSnSₓSe₄₋ₓ, where 0≦x≦4, and the composition of the microparticles is given by Cu₂ZnSnS_{y}Se_{4-y}, where 0≦y≦4, and the difference between x and y is at least about 0.1, 0.2, 0.3, 0.4, 0.5, 0.75, 1, 0, 1.25, 1.5, 1.75, or 2.0. In some embodiments, the molar ratio of Cu to (Zn+Sn) of the CZTS/Se microparticles is MR1 and the molar ratio of Cu to (Zn+Sn) of the CZTS/Se martix is MR2, and the difference between MR1 and MR2 is at least about 0.1, 0.2, 0.3, 0.4, or 0.5. In some embodiments, the molar ratio of Zn to Sn of the CZTS/Se microparticles is MR3 and the molar ratio of Zn to Sn of the CZTS/Se matrix is MR4, and the difference between MR3 and MR4 is at least about 0.1, 0.2, 0.3, 0.4, or 0.5. In some embodiments, the molar ratio of total chalcogen to (Cu+Zn+Sn) of the CZTS/Se microparticles is MR5 and the molar ratio of total chalcogen to (Cu+Zn+Sn) of the CZTS/Se martix is MR6, and the difference between MR5 and MR6 is at least about 0.1, 0.2, 0.3, 0.4, or 0.5. In some embodiments, a dopant is present in the film, and the difference between the wt % of the dopant in the CZTS/Se microparticles and in the inorganic matrix is at least about 0.05, 0.1, 0.2, 0.3, 0.4, 0.5, 0.75, or 1 wt %. In some embodiments, dopants comprise an alkali metal (e.g., Na) or Sb. In some embodiments, a trace impurity is present in the film, and the difference between the wt % of the impurity in the CZTS/Se microparticles and in the inorganic matrix is at least about 0.05, 0.1, 0.2, 0.3, 0.4, 0.5, 0.75, or 1 wt %. In some embodiments, trace impurities comprise one or more of: C, O, Ca, Al, W, Fe, Cr, and N.

In some embodiments, the difference between the average longest dimension of the CZTS/Se microparticles and the average thickness of the annealed film is at least about 0.1, 0.2, 0.3, 0.4, 0.5, 0.75, 1.0, 1.5, 2.0, 2.5, 3.0, 5.0, 10.0, 15.0, 20.0 or 25.0 microns. In some embodiments, the average longest dimension of the CZTS/Se microparticles is less than the average thickness of the annealed film. In some embodiments, the average longest dimension of the CZTS/Se microparticles is less than the average thickness of the annealed film, and the Ra of the annealed film is less than about 1 micron, 0.9 micron, 0.8 micron, 0 7 micron, 0.6 micron, 0.5 micron, 0.4 micron, 0.3 micron, 0.2 micron, 0.1 micron, 0.075 micron, or 0.05 micron, as measured by profilometry. In some embodiments, the average longest dimension of the CZTS/Se microparticles is greater than the average thickness of the annealed film.

It has been found that CZTS-Se can be formed in high yield during the annealing step, as determined by XRD or XAS. In some embodiments, the annealed film consists essentially of CZTS-Se, according to XRD analysis or XAS. In some embodiments, (a) at least about 90%, 95%, 96%, 97%, 98%, 99% or 100% of the copper is present as CZTS/Se in the annealed film, as determined by XAS. This film can be further characterized by: (b) at least about 80%, 85%, 90%, 95%, 96%, 97%, 98%, 99% or 100% of the zinc is present as CZTS/Se, as determined by XAS; and/or (c) at least about 90%, 95%, 96%, 97%, 98%, 99% or 100% of the tin is present as CZTS/Se, as determined by XAS.

Coating and Film Thickness.

By varying the ink concentration and/or coating technique and temperature, layers of varying thickness can be coated in a single coating step. In some embodiments, the coating thickness can be increased by repeating the coating and drying steps. These multiple coatings can be conducted with the same ink or with different inks. As described above, wherein two or more inks are mixed, the coating of multiple layers with different inks can be used to fine-tune stoichiometry and purity of the CZTS-Se films by fine-tuning Cu to Zn to Sn ratios. Soft-bake and annealing steps can be carried out between the coating of multiple layers. In these instances, the coating of multiple layers with different inks can be used to create gradient layers, such as layers that vary in the S/Se ratio. The coating of multiple layers can also be used to fill in voids in the at least one layer and planarize or create an underlayer to the at least one layer, as described above.

The annealed film typically has an increased density and/or reduced thickness versus that of the wet precursor layer. In some embodiments, the film thicknesses of the dried and annealed coatings are 0.1-200 microns; 0.1-100 microns; 0.1-50 microns; 0.1-25 microns; 0.1-10 microns; 0.1-5 microns; 0.1-3 microns; 0.3-3 microns; or 0.5-2 microns.

Purification of Coated Layers and Films.

Application of multiple coatings, washing the coating, and/or exchanging capping agents can serve to reduce carbon-based impurities in the coatings and films. For example, after an initial coating, the coated substrate can be dried and then a second coating can be applied and coated by spin-coating. The spin-coating step can wash organics out of the first coating. Alternatively, the coated film can be soaked in a solvent and then spun-coated to wash out the organics. Examples of useful solvents for removing organics in the coatings include alcohols, e.g., methanol or ethanol, and hydrocarbons, e.g., toluene. As another example, dip-coating of the substrate into the ink can be alternated with dip-coating of the coated substrate into a solvent bath to remove impurities and capping agents. Removal of non-volatile capping agents from the coating can be further facilitated by exchanging these capping agents with volatile capping agents. For example, the volatile capping agent can be used as the washing solution or as a component in a bath. In some embodiments, a layer of a coated substrate comprising a first capping agent is contacted with a second capping agent, thereby replacing the first capping agent with the second capping agent to form a second coated substrate. Advantages of this method include film densification along with lower levels of carbon-based impurities in the film, particularly if and when it is later annealed. Alternatively, binary sulfides and other impurities can be removed by etching the annealed film using techniques such as those used for CIGS films.

### Preparation of Devices, Including Thin-Film Photovoltaic Cells

Another aspect of this invention is a process for preparing a photovoltaic cell comprising a film comprising CZTS/Se microparticles characterized by an average longest dimension of 0.5-200 microns, wherein the microparticles are embedded in an inorganic matrix.

Another aspect of this invention is a photovoltaic cell comprising a film, wherein the film comprises:
a) an inorganic matrix; and
b) CZTS/Se microparticles characterized by an average longest dimension of 0.5-200 microns, wherein the microparticles are embedded in the inorganic matrix.

Various embodiments of the film are the same as described above. In some embodiments, the film is the absorber or buffer layer of a photovoltaic cell. In some embodiments, the photovoltaic cell further comprises a back contact, at least one semiconductor layer, and a front contact, and the average longest dimension of the CZTS/Se microparticles is greater than the average thickness of the annealed film.

Various electrical elements can be formed, at least in part, by the use of the inks and processes described herein. An electronic device can be prepared by depositing one or more layers in layered sequence onto the annealed coating of the substrate. The layers can be selected from the group consisting of: conductors, semiconductors, and insulators.

A typical photovoltaic cell includes, in order, a substrate, a back contact layer (e.g., molybdenum), an absorber layer (also referred to as the first semiconductor layer), a buffer layer (also referred to as the second semiconductor layer), and a top contact layer. The photovoltaic cell can also include an electrode pad on the top contact layer, and an anti-reflective (AR) coating on the front (light-facing) surface of the substrate to enhance the transmission of light into the semiconductor layer. The buffer layer, top contact layer, electrode pads and antireflective layer can be deposited onto the annealed CZTS-Se film

A photovoltaic device can be prepared by depositing the following layers in layered sequence onto the annealed coating of the substrate having an electrically conductive layer present: (i) a buffer layer; (ii) a transparent top contact layer, and (iii) optionally, an antireflective layer. In some embodiments, a photovoltaic device is prepared by disposing one or more layers selected from the group consisting of buffer layers, top contact layers, electrode pads, and antireflective layers onto the annealed CZTS-Se film. In some embodiments, construction and materials for these layers are analogous to those of a CIGS photovoltaic cell. Suitable substrate materials for the photovoltaic cell substrate are as described above.

### INDUSTRIAL UTILITY

Advantages of the inks of the present invention are numerous: 1. The copper, zinc- and tin-containing elemental and chalcogenide particles are easily prepared and, in some cases, commercially available. 2. Combinations of the molecular precursor with CZTS/Se, elemental or chalcogenide particles, particularly nanoparticles, can be prepared that form stable dispersions that can be stored for long periods without settling or agglomeration, while keeping the amount of dispersing agent in the ink at a minimum. 3. The incorporation of elemental particles in the ink can minimize cracks and pinholes in the films and lead to the formation of annealed CZTS films with large grain size. 4. The overall ratios of copper, zinc, tin and chalcogenide in the precursor ink, as well as the sulfur/selenium ratio, can be easily varied to achieve optimum performance of the photovoltaic cell. 5. The use of molecular precursors and/or nanoparticles enables lower annealing temperatures and denser film packing, while the incorporation of microparticles enables the inclusion of larger grain sizes in the film, even with relatively low annealing temperatures. 6. The ink can be prepared and deposited using a low number of operations and scalable, inexpensive processes. 7. Coatings derived from the ink described herein can be annealed at atmospheric pressure. Moreover, for certain ink compositions, only an inert atmosphere is required. For other ink compositions, the use of H₂S or H₂Se is not required to form CZTS/Se, since sulfurization or selenization can be achieved with sulfur or selenium vapor.

In some instances, the film of the present invention comprises CZTS/Se microparticles embedded in an inorganic matrix. Potential advantages of solar cells made from these layers are similar to those of traditional monograin solar cells, wherein the matrix comprises an organic insulator. That is, the CZTS/Se microparticles are fabricated separately from cell production at high temperatures and contribute large grains to the absorber layer, while the molecular and nanoparticle precursors enable low-temperature fabrication of the absorber layer. As compared to an organic matrix, the inorganic matrix potentially offers greater heat, light, and/or moisture stability and an additive effect in capturing light and converting it to current. Another advantage is that such films of the present invention are less prone to cracking.

### Characterization

Useful analytical techniques for characterizing the composition, size, size distribution, density, and crystallinity of the metal chalcogenide nanoparticles, crystalline multinary-metal chalcogenide particles and layers of the present invention include XRD, XAFS (XAS), EDAX, ICP-MS, DLS, AFM, SEM, TEM, ESC, and SAX.

The following is a list of abbreviations and trade names used above and in the Examples:

| Abbreviation | Description |
|---|---|
| XRD | X-Ray Diffraction |
| TEM | Transmission Electron Microscopy |
| ICP-MS | Inductively Coupled Plasma Mass Spectrometry |
| AFM | Atomic Force Microscopy |
| DLS | Dynamic Light Scattering |
| SEM | Scanning Electron Microscopy |
| SAX | Small Angle X-ray Scattering |
| EDX | Energy-Dispersive X-ray Spectroscopy |
| XAFS | X-Ray Absorption Fine Structure |
| CIGS | Copper-Indium-Gallium-Sulfo-di-selenide |
| CZTS | Copper Zinc Tin Sulfide (Cu₂ZnSnS₄) |
| CZTSe | Copper Zinc Tin Selenide (Cu₂ZnSnSe₄) |
| CZTS/Se | All possible combinations of CZTS and CZTSe |
| CTS | Copper Tin Sulfide (Cu₂SnS₃) |
| CTSe | Copper Tin Selenide (Cu₂SnSe₃) |
| CTS/Se | All possible combinations of CTS and CTSe |
| Deg | Degree |
| FW | Formula Weight |
| Ex | Example |
| RTA | Rapid Thermal Annealing |
| EA | Ethanolamine |
| DEA | Diethanolamine |
| TEA | Triethanolamine |
| TMA | Trimethanolamine |
| HMT | Hexamethylenetetramine |
| ED | Ethylene diamine |
| EDTA | Ethylenediamine tetraacetic acid |

### EXAMPLES

### General

Materials.

All reagents were purchased from Aldrich (Milwaukee, Wis.), Alfa Aesar (Ward Hill, Mass.), TCI (Portland, Oreg.), Strem (Newburyport, Mass.), or Gelest (Morrisville, Pa.). Solid reagents were used without further purification. Liquid reagents that were not packaged under an inert atmosphere were degassed by bubbling argon through the liquid for 1 hr. Anhydrous solvents were used for the preparation of all formulations and for all cleaning procedures carried out within the drybox. Solvents were either purchased as anhydrous from Aldrich or Alfa Aesar, or purified by standard methods (e.g., Pangborn, A. G., et. al. Organometallics, 1996, 15, 1518-1520) and then stored in the drybox over activated molecular sieves.

Formulation and Coating Preparations.

Substrates (SLG slides) were cleaned sequentially with aqua regia, Miilipore® water and isopropanol, dried at 110° C., and coated on the non-float surface of the SLG substrate. All formulations and coatings were prepared in a nitrogen-purged drybox. Vials containing formulations were heated and stirred on a magnetic hotplate/stirrer. Coatings were dried in the drybox.

Annealing of Coated Substrates in a Tube Furnace.

Annealings were carried out either under an inert atmosphere (nitrogen or argon) or under an inert atmosphere comprising a chalcogen source (nitrogen/sulfur or argon/sulfur). Annealings were carried out in either a single-zone Lindberg/Blue (Ashville, N.C.) tube furnace equipped with an external temperature controller and a one-inch quartz tube, or in a Lindberg/Blue three-zone tube furnace (Model STF55346C) equipped with a three-inch quartz tube. A gas inlet and outlet were located at opposite ends of the tube, and the tube was purged with nitrogen or argon while heating and cooling. The coated substrates were placed on quartz plates inside of the tube.

When annealing under sulfur, a 3-inch long ceramic boat was loaded with 2.5 g of elemental sulfur and placed near the gas inlet, outside of the direct heating zone. The coated substrates were placed on quartz plates inside the tube.

When annealing under selenium, the substrates were placed inside of a graphite box (Industrial Graphite Sales, Harvard, Ill.) with a lid with a center hole in it of 1 mm in diameter. The box dimensions were 5″ length×1.4″ width×0.625″ height with a wall and lid thickness of 0.125″. The selenium was placed in small ceramic boats within the graphite box.

### Details of the Procedures Used for Device Manufacture

Mo-Sputtered Substrates.

Substrates for photovoltaic devices were prepared by coating an SLG substrate with a 500 nm layer of patterned molybdenum using a Denton Sputtering System. Deposition conditions were: 150 watts of DC Power, 20 sccm Ar, and 5 mT pressure. Alternatively, Mo-sputtered SLG substrates were purchased from Thin Film Devices, Inc. (Anaheim, Calif.).

Cadmium Sulfide Deposition.

CdSO₄ (12.5 mg, anhydrous) was dissolved in a mixture of nanopure water (34.95 mL) and 28% NH₄OH (4.05 mL). Then a 1 mL aqueous solution of 22.8 mg thiourea was added rapidly to form the bath solution. Immediately upon mixing, the bath solution was poured into a double-walled beaker (with 70° C. water circulating between the walls), which contained the samples to be coated. The solution was continuously stirred with a magnetic stir bar. After 23 min, the samples were taken out, rinsed with and then soaked in nanopure water for 1 hr. The samples were dried under a nitrogen stream and then annealed under a nitrogen atmosphere at 200° C. for 2 min.

Insulating ZnO and AZO Deposition.

A transparent conductor was sputtered on top of the CdS with the following structure: 50 nm of insulating ZnO (150 W RF, 5 mTorr, 20 sccm) followed by 500 nm of Al-doped ZnO using a 2% Al₂O₃, 98% ZnO target (75 or 150 W RF, 10 mTorr, 20 sccm).

ITO Transparent Conductor Deposition.

A transparent conductor was sputtered on top of the CdS with the following structure: 50 nm of insulating ZnO [100 W RF, 20 mTorr (19.9 mTorr Ar+0.1 mTorr O₂)] followed by 250 nm of ITO [100 W RF, 12 mTorr (12 mTorr Ar+5×10⁻⁶ Torr O₂)]. The sheet resistivity of the resulting ITO layer is approximately 30 ohms per square.

Deposition of Silver Lines.

Silver was deposited at 150 WDC, 5 mTorr, 20 sccm Ar, with a target thickness of 750 nm.

### Details of X-ray, IV, EQE, and OBIC Analysis.

XAS Analysis.

XANES spectroscopy at the Cu, Zn and Sn K-edges were carried out at the Advanced Photon Source at the Argonne National Laboratory. Data were collected in fluorescence geometry at beamline 5BMD, DND-CAT. Thin-film samples were presented to the incident x-ray beam as made. An Oxford spectroscopy-grade ion chamber was used to determine the X-ray incident intensity (I₀). The I₀ detector was filled with 570 Torr of N₂ and 20 Torr of Aur. The fluorescence detector was a Lytle Cell filled with Xe installed perpendicular to the beam propagation direction. Data were collected from 8879 eV to 9954 eV for the Cu edge. The high final energy was used in order to capture a portion of the Zn edge in the same data set, to allow edge step ratio determination as an estimate of Cu:Zn ratio in the film. The Zn edge data were collected over the range 9557 eV to 10,404 eV. Sn edge data covered the range of 29,000 eV to 29,750 eV. The data energy scales were calibrated based on data from metal reference foils collected prior to sample data collection. A second order background was subtracted and the spectra were normalized. Data from several Cu, Zn and Sn sulfide, selenide, and oxide standards (Cu₂ZnSnS₄, Cu₂ZnSnSe₄, Cu₂SnS₃, CuS, Cu₂S, CuSe, Cu₂Se, CuO, Cu₂O, ZnS, ZnSe, ZnO, SnS, SnSe, SnO and SnO₂) were obtained under the same conditions. Non-linear least squares fitting of a linear combination of the appropriate standards to the spectra obtained from the samples yielded the phase distribution for each element.

XRD Analysis.

Powder X-ray diffraction was used for the identification of crystalline phases. Data were obtained with a Philips X'PERT automated powder diffractometer, Model 3040. The diffractometer was equipped with automatic variable anti-scatter and divergence slits, X'Celerator RTMS detector, and Ni filter. The radiation was CuK(alpha) (45 kV, 40 mA). Data were collected at room temperature from 4 to 120°. 2-theta; using a continuous scan with an equivalent step size of 0.02°; and a count time of from 80 sec to 240 sec per step in theta-theta geometry. Thin-film samples were presented to the X-ray beam as made. MDI/Jade software version 9.1 was used with the International Committee for Diffraction Data database PDF4+ 2008 for phase identification and data analysis.

IV Analysis.

Current (I) versus voltage (V) measurements were performed on the samples using two Agilent 5281B precision medium power SMUs in a E5270B mainframe in a four point probe configuration. Samples were illuminated with an Oriel 81150 solar simulator under 1 sun AM 1.5G.

EQE Analysis.

External Quantum Efficiency (EQE) determinations were carried out as described in ASTM Standard E1021-06 (“Standard Test Method for Spectral Responsivity Measurements of Photovoltaic Devices”). The reference detector in the apparatus was a pyroelectric radiometer (Laser Probe (Utica, N.Y.), LaserProbe Model RkP-575 controlled by a LaserProbe Model Rm-6600 Universal Radiometer). The excitation light source was a xenon arc lamp with wavelength selection provided by a monochrometer in conjunction with order sorting filters. Optical bias was provided by a broad band tungsten light source focused to a spot slightly larger than the monochromatic probe beam. Measurement spot sizes were approximately 1 mm×2 mm.

OBIC Analysis.

Optical beam-induced current measurements were determined with a purpose-constructed apparatus employing a focused monochromatic laser as the excitation source. The excitation beam was focused to a spot ˜100 microns in diameter. The excitation spot was rastered over the surface of the test sample, while simultaneously measuring photocurrent so as to build a map of photocurrent vs position for the sample. The resulting photocurrent map characterizes the photoresponse of the device vs. position. The apparatus can operate at various wavelengths via selection of the excitation laser. Typically, 440, 532 or 633 nm excitation sources were employed.

### Details of Particle Synthesis and Characterization

Particle Size Distribution (PSD).

The PSD was measured with a Beckman Coulter LS13320 using laser diffraction to determine the volume distribution of a field of particles. An aliquot of the powder (˜0.1 g) was mixed with 1 drop of Surfynol® (a surfactant to promote wetting) and 20 mL of deionized water and sonified by ultrasonic probe for one minute. A portion of this was added to the instrument which was also filled with deionized water. Two repeat runs were made as a check on sample stability and on instrument reproducibility.

SAXS Analysis.

Determination of particle sizes and distributions by SAXS was carried out using a USAXS double crystal, Bonse-Hart, from Rigaku. Samples were analyzed as a single layer (˜50 microns thick) of crystallites on sticky tape. Desmearing and analysis were conducted as contained in a standard package for IGOR.

Synthesis of CZTS Crystals.

Copper(II) sulfide (4.35 g, 0.0455 mol), zinc(II) sulfide (2.22 g, 0.0228 mol), and tin(IV) sulfide (4.16 g, 0.0228 mol) were mixed together by shaking for 15 min. The mixture was placed in a 20 mL alumina boat, which was then put into a tube furnace with nitrogen flow. The boat was heated from ambient temperature to 800° C. in 15 min, and kept at this temperature for 1 day. The sample was cooled down to ambient temperature, ground, and then placed back into the boat and the tube furnace under nitrogen flow. The heating cycle was then repeated. This procedure was repeated 4 times, giving a total heating time of 5 days. The sample was analyzed by XRD to confirm the presence of CZTS crystals. In some instances, the crystals were ground to provide a fine powder and sieved through a 345 micron mesh. In some instances, the crystals were media-milled to provide microparticles with D50 of 1.0078 microns and D95 of 2.1573 microns, according to PSD analysis.

Aqueous Synthesis of CZTS Particles.

Aqueous stock solutions were prepared in nanopure water. Solutions of CuSO₄ (3.24 mmol; 0.4 M), ZnSO₄ (1.4 mmol; 0.8 M), and SnCl₄ (1.575 mmol, 0.7 M) were mixed together in a round bottom flask equipped with a stir bar. Next, solutions of NH₄NO₃ (1 mmol; 0.4 M) and triethanolamine (TEA, 3.8 mmol, 3.7 M) were sequentially added to the reaction mixture. Sulfuric acid was used to adjust the pH to 1, and the reaction mixture was stirred for 30 min, followed by the addition of aqueous thioacetamide (TAA, 27.6 mmol, 0.4 M). The flask was placed in a hot water bath with magnetic stirring and the reaction temperature was maintained at 80° C. for 2.5 hr to provide a black suspension. Next, the water bath was removed, and the flask was allowed to cool to room temperature. The resulting precipitate was collected via decantation/centrifugation. The solids were washed three times with water, and then portions of the material were dried overnight in a vacuum oven at 45° C. to provide a black powder that represents the as-synthesized mixture of Cu, Zn, and Sn sulfide nanoparticles. The nanoparticles were placed in a quartz boat and were thermally treated at 550° C. under a nitrogen and sulfur atmosphere in a 2-inch tube furnace for 2 hr to provide high purity CZTS particles with a kesterite structure, as confirmed by XRD, HR-TEM, XAS and XRF. Analysis by SAXS indicated the formation of particles ranging from 0.1 to 1.0 micron in size.

### Example 1

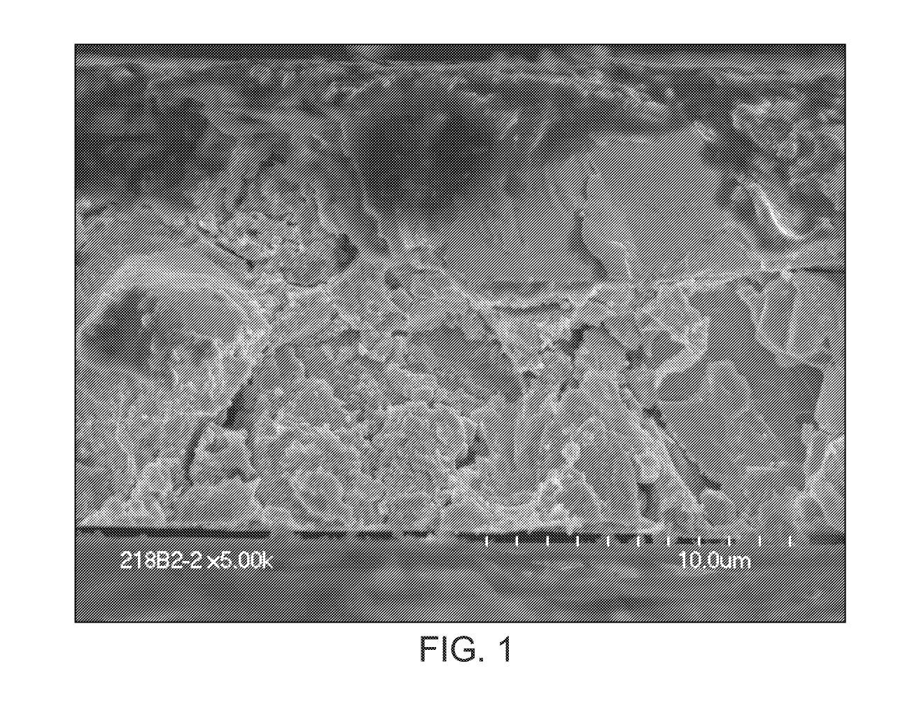

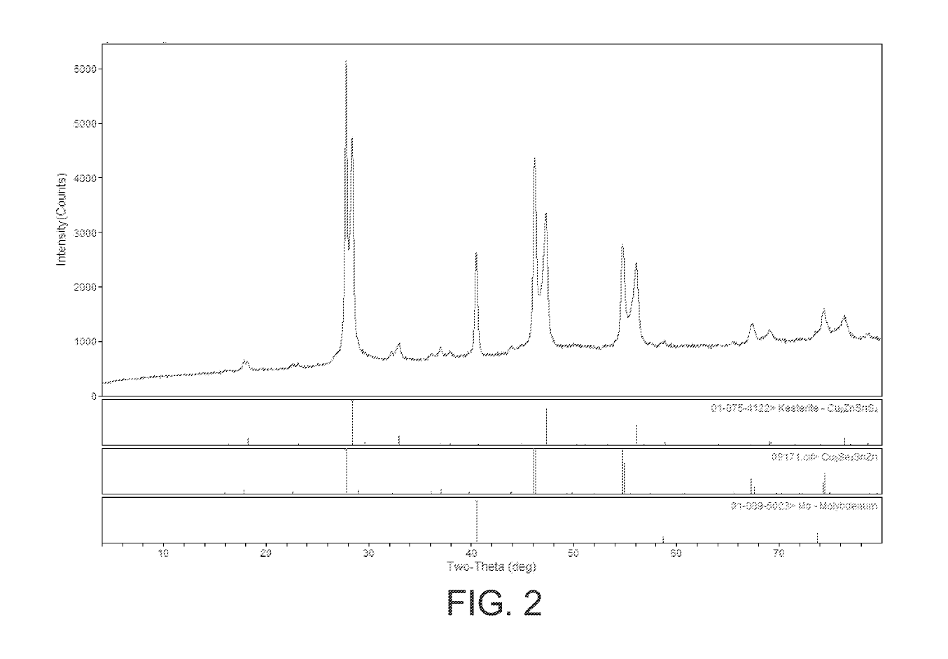

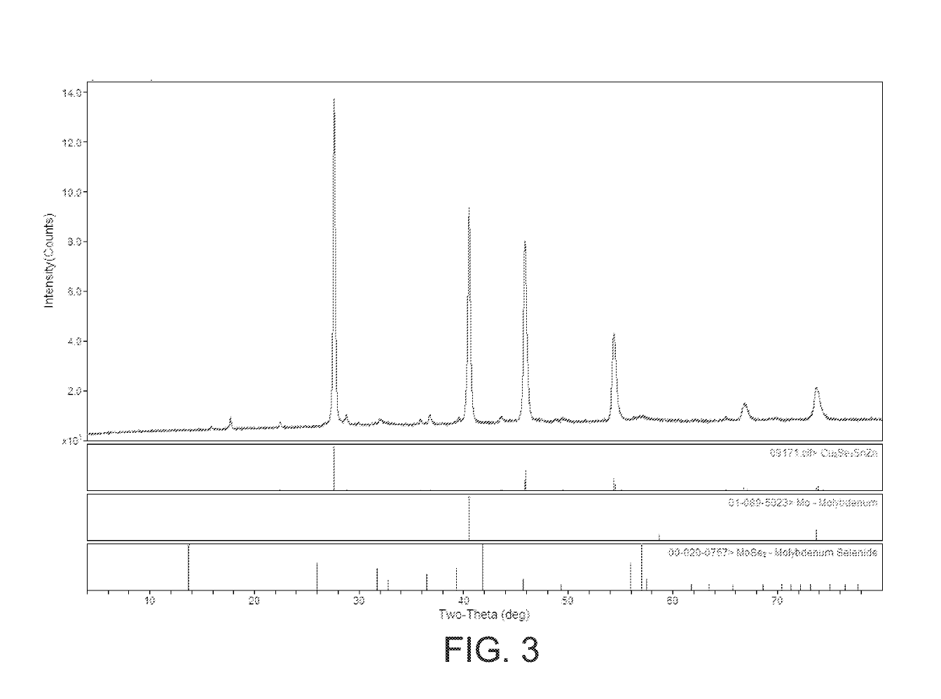

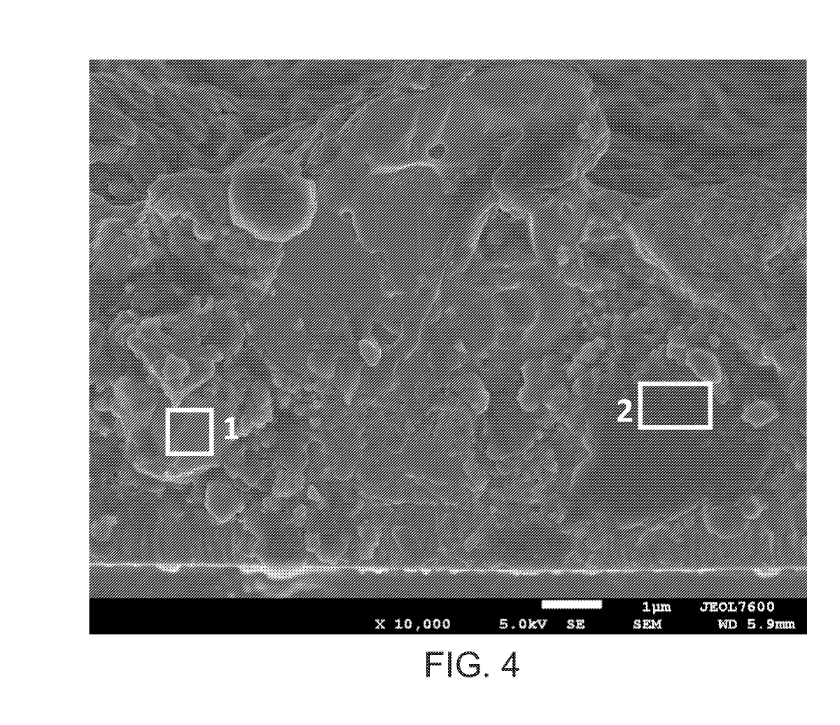

Example 1 illustrates the preparation of an ink from a combination of molecular precursor and sieved CZTS microcrystals, prepared as described above. An active photovoltaic device was produced from an annealed film of the ink in Example 1A. The SEM cross-section of the film is shown in FIG. 1 and demonstrates the presence of large microcrystalline domains (approximately 10 microns in size) embedded in a dense matrix. In Example 1B, an annealed was prepared from an ink containing the molecular precursor of Example 1 combined with CZTS particles prepared by the aqueous route. The XRD of the annealed film (FIG. 2) indicated the presence of both CZTS and CZTS/Se and was consistent with CZTS particles embedded in a CZTS/Se matrix. In Example 1C, only CZTS/Se was observed by XRD (FIG. 3) for a film prepared from an ink containing the molecular precursor of Example 1 combined with sieved CZTS microcrystals. However, EDX data for areas centered on a particle and on the matrix of the SEM cross-section (FIG. 4) of this film indicated that the particle-centered area contained greater wt % of calcium impurities relative to the matrix and that the CZTS/Se matrix was Sn-deficient relative to the particle.

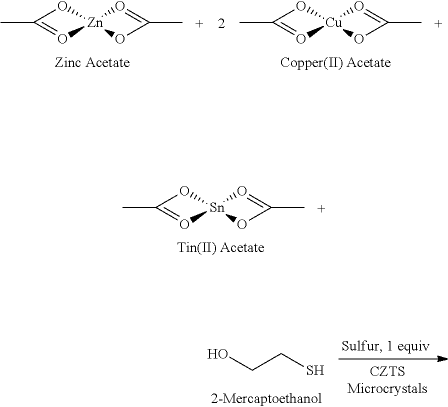

In the drybox, 1.2352 g of a 2:1 mixture of pyridine and 2-aminopyridine, copper(II) acetate (0.5807 g, 3.197 mmol), zinc acetate (0.3172 g, 1.729 mmol), tin(II) acetate (0.4035 g, 1.704 mmol), mercaptoethanol (1.0669 g, 13.655 mmol), and sulfur (0.0513 g, 1.600 mmol) were sequentially added with mixing to an amber 40 mL vial equipped with a stir bar. The vial was capped with a septum and the reaction mixture was stirred for ˜12 hr at room temperature. Next, the septum was vented and the reaction mixture was stirred for ˜40 hr at a first heating temperature of 105° C. The reaction mixture was then allowed to cool to room temperature. The resulting ink was diluted with 1.0348 g of a 2:1 mixture of pyridine and 2-aminopyridine to provide a clear brown solution. A portion of the resulting mixture (1.0305 g), sieved CZTS microcrystals (0.2001 g), and 0.3111 g of a 2:1 mixture of pyridine and 2-aminopyridine were placed in a 40 mL vented septum-capped amber vial equipped with a stir bar. The resulting mixture was stirred at a temperature of 105° C. for ˜24 hr.

An SLG slide was coated via spin-coating according to the following procedure: A small portion of the ink was drawn into a pipette and dropped onto the substrate, which was then spun at 1500 rpm for 8 sec.

The coating was then dried in the drybox at 170° C. for 15 min and then at 230° C. for 10 min on a hotplate. The coating and drying procedure was repeated (1750 rpm for 8 sec and dried at 170° C. for 30 min). The dried sample was annealed under an argon atmosphere in a 3-inch tube. The temperature was raised to 250° C. at a rate of 15° C./min and then raised to 500° C. at a rate of 2° C./min. The temperature was held at 500° C. for 1 hr before allowing the tube to cool to room temperature. Analysis of the annealed sample by XRD confirmed the presence of highly crystalline CZTS and a small amount of wurtzite ZnS.

### Example 1A

An annealed film on a Mo-coated glass substrate was formed in an analogous fashion to the film of Example 1. Cadmium sulfide, an insulating ZnO layer, an ITO layer, and silver lines were deposited. The resulting device exhibited a very small PV effect (efficiency less than 0.001%) with J90 of 2.8 micro-Amp and dark current of 0.65 micro-Amp as measured by OBIC at 440 nm. EQE was measured with an onset at 880 nm and an EQE of 0.26% at 640 nm.

### Example 1B

The molecular precursor of Example 1 was synthesized on twice the scale. In the drybox, the Cu, Zn, and Sn reagents and the sulfur were placed together in a 40 mL amber vial, which was then cooled to −25° C. In a separate vial, 2.5 g of a 2:1 mixture of pyridine/3-aminopyridine was also cooled to −25° C. The cold solvent mixture was added to the cold vial containing the reagents. Following mixing, the reaction mixture was cooled to −25° C. again. A vial containing the mercaptoethanol was also cooled to −25° C. The cold mercaptoethanol was then added dropwise via pipet to the cold reaction mixture. The reaction mixture was then stirred for 66 hr at room temperature. Additional pyridine (2.5 g) was added to the mixture prior to heating it at 100° C. for 7 days. After allowing the reaction mixture to cool to room temperature, 0.89 g of 3,5-lutidine and 1.06 g of 1-butanethiol was added. Following mixing, the resulting molecular precursor ink was filtered twice through small plugs (˜0.5 cm) of glass wool in pipets. Following removal of ˜1 mL of the ink, an additional 1.45 mL of butanethiol was added to the remaining ink. The diluted molecular precursor ink was mixed and filtered again using a pipet with a plug of glass wool. 1.5 g of the resulting ink was mixed with 0.52 g of CZTS particles, which were prepared according to the above aqueous synthesis. The particle-containing ink was stirred for 3 days. A small portion of the ink was drawn into a pipette and spread onto a Mo-sputtered SLG substrate. After allowing the ink to sit on the substrate for several minutes, it was spun at 520 rpm for 3 sec. The coating was then dried in the drybox at 175° C. for ˜30 min on a hotplate. The same coating and drying procedure was repeated to form a second coated layer. The substrate was placed in a graphite box along with four other substrates and three ceramic boats containing a total of 150 mg of Se pellets. The box was placed in a 3-inch tube furnace which was evacuated and then placed under argon. The temperature was increased to 585° C. Once it reached the set point, the tube was allowed to cool to 500° C. and held there for 30 min. The XRD (FIG. 2) of the annealed film had peaks for Mo, CZTS, and CZTS/Se. The coherent domain size was 25.3+/−0.6 nm for the CZTS and 72.1+/−2.5 nm for the CZTS/Se, as determined from the full width at half maximum intensity. The CZTS/Se had a sulfur/selenium ratio of 46.9/53.1. For comparison, the sulfur/selenium ratio in an annealed film prepared from only the molecular precursor was 19/81, according to XRD.

### Example 1C

An ink was prepared according to Example 1B, except that 0.52 g of sieved CZTS microcrystals were used in place of the CZTS particles from the aqueous synthesis. The procedure of Example 1B was followed in preparing the first coated layer on a Mo substrate. A molecular precursor ink of similar composition to that of the diluted molecular precursor of 1B was spun on top of the particle-containing layer by spreading the molecular precursor on top of the dried coating and letting it sit for several minutes. It was then spun for 3 sec at 610 rpm and then dried at 175° C. for ˜30 min on a hotplate. The substrate was placed in a graphite box along with four other substrates and three ceramic boats containing a total of 150 mg of Se pellets. The box was placed in a 3-inch tube furnace which was evacuated and then placed under argon. The temperature was increased to 600° C. Once it reached the set point, the tube was cooled to 500° C. by opening the oven briefly and then held at 500° C. for 30 min. The XRD of the annealed film (FIG. 3) had peaks for Mo, CZTS/Se and trace MoSe₂. The coherent domain size was 63.2+/−1.2 nm for the CZTS/Se, as determined from the full width at half maximum intensity. The CZTS/Se had a sulfur/selenium ratio of 32.6/67.4, according to XRD. The substrate was broken in half and an SEM image (FIG. 4) of the cross-section was acquired along with EDX data on two areas that occurred at similar depths in the film: the particle-centered area 1 and the matrix-centered area 2. According to the EDX data, the Cu:Zn:Sn:S:Se atom percents (+/−1 Sigma) of areas 1 and 2, respectively were as follows: 11.14 (+/−0.10) Cu, 5.26 (+/−0.10) Zn, 5.43 (+/−0.07) Sn, 15.27 (+/−0.10) S, 13.25 (+/−0.17) Se for area 1; and 10.65 (+/−0.07) Cu, 4.55 (+/−0.07) Zn, 3.24 (+/−0.05) Sn, 13.22 (+/−0.07) S, 12.20 (+/−0.12) Se. The Zn/Sn ratio is 0.97 for area 1 and 1.40 for area 2. The ratio of Cu/(Zn+Sn) is 1.04 for area 1 and 1.37 for area 2. The wt % of Ca is 0.61 (+/−0.06) wt % for area 1 and 0.34 (+/−04) wt % for area 2.

### Example 2

This example illustrates the preparation of an ink from a combination of molecular precursor and media-milled CZTS microcrystals, prepared as described above. It also illustrates the formation of an annealed film comprising a bottom layer prepared from the molecular precursor/microcrystal ink and a top layer comprising the molecular precursor alone. An active photovoltaic device was produced from an annealed film of the ink and exhibited improved activity over a device made from a film of the molecular precursor alone (comparative Example 2B).

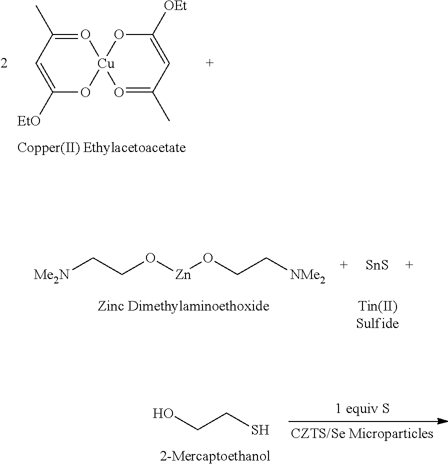

In the drybox, 2.2929 g of a 2:1 mixture of t-butylpyridine and 2-aminopyridine, copper(II) ethylacetoacetate (1.0377 g, 3.225 mmol), zinc dimethylaminoethoxide (0.4032 g, 1.669 mmol), tin(II) sulfide (0.2475 g, 1.642 mmol), mercaptoethanol (0.8106 g, 10.375 mmol), and sulfur (0.0528 g, 1.646 mmol) were sequentially added with mixing to an amber 40 mL vial equipped with a stir bar. The vial was capped with a septum and the reaction mixture was stirred for ˜12 hr at room temperature and then ˜40 hr at a first heating temperature of 105° C. Next, the septum was vented and the reaction mixture was stirred for ˜8 hr at a second heating temperature of 170° C. The reaction mixture was then allowed to cool to room temperature. A portion of the resulting mixture (1.0127 g) and 0.2018 g of media-milled CZTS microcrystals were placed in a 40 mL septum-capped amber vial equipped with a stir bar. The resulting mixture was stirred at a temperature of 105° C. for 5 hr.

An SLG slide was coated via spin-coating according to the following procedure: While being maintained at 105° C. with stirring, a small portion of the ink was drawn into a pipette and spread onto the substrate, which was then spun at 450 rpm for 9 sec and then at 3000 rpm for 3 sec. The coating was then dried in the drybox at 230° C. for ˜10 min on a hotplate. Next, a small portion of an ink containing only the molecular precursor was spread on top of the coated substrate, which was then spun at 450 rpm for 18 sec and at 1000 rpm for 10 sec. The bilayer coating was then dried in the drybox at 230° C. for ˜10 min on a hotplate. The dried sample was annealed under argon at 500° C. for 1.5 hr in a 3-inch tube and then under a nitrogen/sulfur atmosphere at 500° C. for 1 hr in a 1-inch tube. Analysis of the annealed sample by XRD confirmed the presence of CZTS.

### Example 2A

The particle-containing ink of Example 2 was heated for an additional 5 days at 105° C. The ink was then diluted with t-butylpyridine and a portion of it was spread onto a Mo-patterned SLG slide and spun for 18 sec at 450 rpm and then for 5 sec at 1000 rpm. The coating was then dried in the drybox at 230° C. for ˜10 min on a hotplate. The coating procedure (spun at 18 sec at 450 rpm only) and drying procedure were then repeated. The dried sample was annealed under an argon atmosphere at 500° C. for 2 hr in a 3-inch tube. Cadmium sulfide, an insulating ZnO layer, an ITO layer, and silver lines were deposited. The resulting device exhibited an efficiency 0.013% and gave a photoresponse with J90 of 8.4 micro-Amp and dark current of 0.7 micro-Amp as measured by OBIC at 440 nm. EQE was measured with an onset at 880 nm and an EQE of 1.7% at 640 nm. Profilometry was acquired and the data was analyzed using a 25 micron low-pass filter. The film had a thickness of 3.20 micron with Ra of 256 nm and Wa of 312 nm.

### Comparative Example 2B

Sixteen devices were prepared from annealed films derived from an analogous ink containing only the molecular precursor (the zinc source was zinc methoxyethoxide). The most promising device exhibited a very small PV effect (efficiency less than 0.001%) with J90 of 2.0 micro-Amp and dark current of 0.7 micro-Amp as measured by OBIC at 440 nm. EQE was measured with an onset at 880 nm and an EQE of 0.09% at 640 nm.

### Example 3

This example illustrates the preparation of an ink from a combination of molecular precursor and CZTS particles, synthesized as described above by an aqueous route. An active photovoltaic device was produced from an annealed film of the ink. As illustrated by the comparative Example 3B, the particles exhibited poor adhesion to the substrate in the absence of the molecular precursor component of the ink.

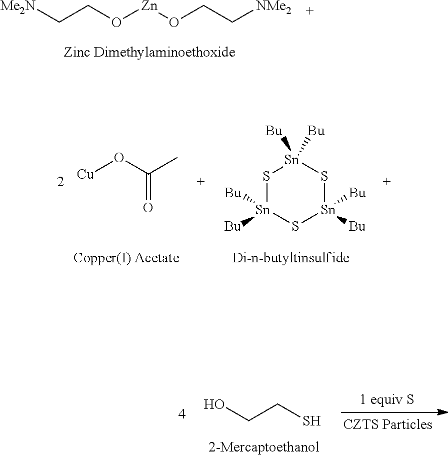

Zinc dimethylaminoethoxide (0.4119 g, 1.705 mmol), copper(I) acetate (0.3803 g, 3.102 mmol), and 2-mercaptoethanol (0.5686 g, 7.278 mmol) were placed in a 40 mL amber septum-capped vial equipped with a stir bar. Pyridine (0.8 g) and 3-aminopyridine (0.4 g) were added, and the resulting mixture was stirred well. Next, 0.0526 g (1.640 mmol) of elemental sulfur was added. The reaction mixture was stirred for 19 days at room temperature. Next, di-n-butyltinsulfide (0.4623 g, 1.745 mmol) was added to the reaction mixture, which was stirred for an additional 48 h at room temperature. The reaction mixture was then heated for ˜40 hr at 105° C. The reaction mixture was then allowed to cool to room temperature. A portion of the resulting mixture (1.0129 g) was placed in a 40 mL septum-capped amber vial equipped with a stir bar and 0.2008 g of CZTS particles, which were prepared according to the above aqueous synthesis. The mixture was stirred at a temperature of 105° C. for 5 hr.

An SLG slide was coated via spin-coating according to the following procedure: While being maintained at 105° C. with stirring, a small portion of the formulation was drawn into a pipette and spread onto the substrate, which was then spun at 450 rpm for 9 sec and then at 3000 rpm for 3 sec. The coating was then dried in the drybox at 230° C. for ˜10 min on a hotplate. The dried sample was annealed under argon at 500° C. for 1.5 hr in a 3-inch tube and then under a nitrogen/sulfur atmosphere at 500° C. for 1 hr in a 1-inch tube. Analysis of the annealed sample by XRD confirmed the presence of CZTS.

### Example 3A

The ink of Example 3 was diluted with 0.5 mL of pyridine and heated for an additional 5 days at 105° C. The ink was spread onto a Mo-patterned SLG slide and spun for 18 sec at 450 rpm and then for 5 sec at 1000 rpm. The coating was then dried in the drybox at 230° C. for ˜10 min on a hotplate. The coating and drying procedures were then repeated. The dried sample was annealed under an argon atmosphere at 500° C. for 2 hr in a 3-inch tube. Cadmium sulfide, an insulating ZnO layer, an ITO layer, and silver lines were deposited. Of two devices, device 1 exhibited an efficiency of 0.167% and gave a photoresponse with J90 of 12 micro-Amp and dark current of 0.2 micro-Amp as measured by OBIC at 440 nm. Device 2 exhibited an efficiency of 0.062% and gave a photoresponse with J90 of 13 micro-Amp and dark current of 0.1 micro-Amp as measured by OBIC at 440 nm. EQE was measured for device 2 with onset at 900 nm and an EQE of 6.11% at 640 nm. Profilometry was acquired and the data was analyzed using a 25 micron low-pass filter. The film had a thickness of 2.96 microns, with a Ra of 328 nm and a Wa of 139 nm.

### Comparative Example 3B

For comparison with the devices of Example 3A, an attempt was made to prepare a device from the CZTS particles following similar procedures to those given in Examples 3 and 3A. In the absence of the molecular precursor component of the ink, the attempt to make a device was unsuccessful, as the film made from the CZTS/Se particles was powdery and exhibited poor adhesion to the Mo-coated substrate.

### Examples 4A and 4B

In these examples, XAS analysis indicates the formation of high-purity, zinc-rich CZTS films derived from inks made from molecular precursors and CZTS particles prepared by an aqueous synthesis, as described above.

### Example 4A

The composition and preparation of the molecular precursor portion of the ink was as in Example 2, with the exception that zinc acetate was used as the zinc source. A portion of the ink (1.0225 g) was then combined with 2.039 g of CZTS particles prepared by an aqueous synthesis. The mixture was stirred at a temperature of 105° C. for 5 hr.

An SLG slide was coated via spin-coating according to the following procedure: A small portion of the ink was drawn into a pipette and spread onto the substrate, which was then spun at 450 rpm for 9 sec and then at 3000 rpm for 3 sec. The coating was then dried in the drybox at 230° C. for ˜10 min on a hotplate. The coating/drying procedure was repeated 3 times: (1) with the particle-containing ink, (2) with the molecular precursor, and (3) with the particle-containing ink. The dried sample was annealed under argon at 500° C. for 1.5 hr in a 3-inch tube and then under a nitrogen/sulfur atmosphere at 500° C. for 1 hr in a 1-inch tube. According to XAS analysis, 100% of the Cu and 92% of the Zn present in the film were present as kesterite. The overall ratio of Cu:Zn in the film was 2:1.09 and the ratio of Cu:Zn in kesterite was 2:1.01.

### Example 4B

The molecular precursor portion of the ink was prepared according to the procedure of Example 2 using 2.002 g of a 1:1 mixture of t-butylpyridine and 2-aminopyridine, copper(II) bis(2-hydroxyethyl) dithiocarbamate (1.3716 g, 3.234 mmol), zinc dimethylaminoethoxide (0.4056 g, 1.679 mmol), tin(II) sulfide (0.2479 g, 1.644 mmol), mercaptoethanol (0.2804 g, 3.589 mmol), and sulfur (0.0533 g, 1.662 mmol). A portion of the molecular precursor (1.0322 g) was then combined with 2.091 g of CZTS particles prepared by an aqueous synthesis. The mixture was stirred at a temperature of 105° C. for 5 hr.

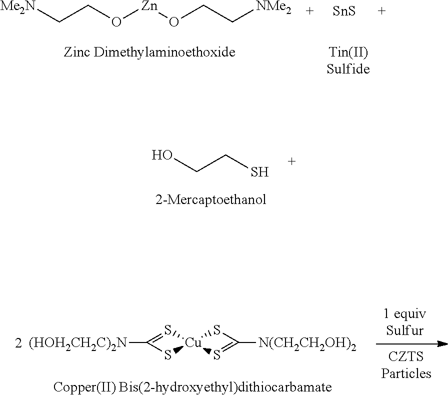

An SLG slide was coated via spin-coating according to the following procedure: A small portion of the ink was drawn into a pipette and spread onto the substrate, which was then spun at 450 rpm for 9 sec and then at 3000 rpm for 3 sec. The coating was then dried in the drybox at 230° C. for ˜10 min on a hotplate. Next, the remaining ink was diluted with 0.5 mL of t-butylpyridine and the coating and drying procedures were repeated. The dried sample was annealed under argon at 500° C. for 1.5 hr in a 3-inch tube and then under a nitrogen/sulfur atmosphere at 500° C. for 1 hr in a 1-inch tube. According to XAS analysis, 94% of the Cu and 97% of the Zn present in the film were present as kesterite. The overall ratio of Cu:Zn in the film was 2:1.10 and the ratio of Cu:Zn in kesterite was 2:1.14.

### Example 5

This example illustrates the preparation of an ink in which the microcrystals have a different composition than the molecular precursor. The ink is formed from CZTS/Se molecular precursor and sieved CZTS microcrystals, prepared as described above. The XRD of an annealed film prepared from the ink confirmed the presence of both CZTSe and CZTS. An active photovoltaic device was produced from an annealed film of the ink.

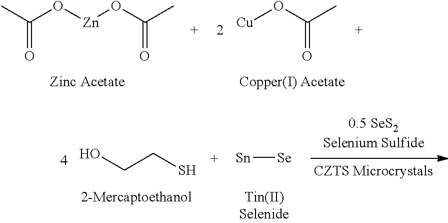

The molecular precursor portion of the ink was prepared according to the procedure of Example 1 using 2.000 g of a 3:2 mixture of 5-ethyl-2-methylpyridine and 2-aminopyridine, copper(I) acetate (0.7820 g, 6.379 mmol), zinc acetate (0.6188 g, 3.373 mmol), tin(II) selenide (0.6413 g, 3.261 mmol), mercaptoethanol (1.1047 g, 14.139 mmol), and selenium sulfide (0.2347 g, 1.640 mmol). The preparation of two more batches of this molecular precursor was carried out in a similar manner with the following exceptions: half the scale of reagents was used, the copper reagent was added last, and 1.25 g of a 3:2 mixture of 3,5-lutidine and 2-aminopyridine was used as the vehicle. All three molecular precursors were combined and mixed with 2 mL of a 3:2 mixture of 5-ethyl-2-methylpyridine and 2-aminopyridine. A portion of this combined molecular precursor (1.0339 g) was then combined with 2.0008 g of sieved CZTS microcrystals, prepared as described above, and 0.2096 g of a 3:2 mixture of 3,5-lutidine and 2-aminopyridine. The particle-containing ink was stirred at a temperature of 100° C. for greater than 24 hr.

An SLG slide was coated via spin-coating according to the following procedure: A small portion of the ink was drawn into a pipette and dropped onto the substrate, which was then spun at 1500 rpm for 10 sec. The coating was then dried in the drybox at 170° C. for 15 min and then at 230° C. for 10 min on a hotplate. The coating and drying procedure was repeated (2500 rpm for 8 sec). The dried sample was annealed under an argon atmosphere in a 3-inch tube. The temperature was raised to 250° C. at a rate of 15° C./min and then raised to 500° C. at a rate of 2° C./min. The temperature was held at 500° C. for 1 hr before allowing the tube to cool to room temperature. Analysis of the annealed sample by XRD confirmed the presence of both CZTSe and CZTS with small amounts of ZnSe and CuSe.

### Example 5A

An annealed film on a Mo-coated glass substrate was formed in an analogous fashion to the film of Example 5. Cadmium sulfide, an insulating ZnO layer, an ITO layer, and silver lines were deposited. The resulting device exhibited had an efficiency of 0.007% with J90 of 7.8 micro-Amp and dark current of 0.53 micro-Amp as measured by OBIC at 440 nm. EQE was measured with an onset at 940 nm and an EQE of 1.07% at 640 nm.

What is claimed is:

1. An ink comprising:
a) a molecular precursor to CZTS/Se, comprising:
i) a copper source selected from the group consisting of copper complexes of N-, O-, C-, S-, and Se-based organic ligands, copper sulfides, copper selenides, and mixtures thereof;
ii) a tin source selected from the group consisting of tin complexes of N-, O-, C-, S-, and Se-based organic ligands, tin hydrides, tin sulfides, tin selenides, and mixtures thereof;
iii) a zinc source selected from the group consisting of zinc complexes of N-, O-, C-, S-, and Se-based organic ligands, zinc sulfides, zinc selenides, and mixtures thereof; and
iv) a vehicle, comprising a liquid chalcogen compound, a liquid tin source, a solvent, or a mixture thereof; and
b) a plurality of particles selected from the group consisting of: CZTS/Se particles; elemental Cu-, elemental Zn- or elemental Sn-containing particles; binary or ternary Cu-, Zn- or Sn-containing chalcogenide particles; and mixtures thereof.

2. The ink of claim 1, wherein at least one of the molecular precursor or the ink has been heat-processed at temperature of greater than about 100° C.

3. The ink of claim 1, wherein the molar ratio of Cu:Zn:Sn is about 2:1:1.

4. The ink of claim 1, wherein the molecular precursor comprises a chalcogen compound selected from the group consisting of: elemental S, elemental Se, CS₂, CSe₂, CSSe, R¹S—Z, R¹Se—Z, R¹S—SR¹, R¹Se—SeR¹, R²C(S)S—Z, R²C(Se)Se—Z, R²C(Se)S—Z, R¹C(O)S—Z, R¹C(O)Se—Z, and mixtures thereof, with each Z independently selected from the group consisting of: H, NR⁴₄, and SiR⁵₃; wherein each R¹ and R⁵ is independently selected from the group consisting of: hydrocarbyl and O-, N-, S-, halogen- and tri(hydrocarbyl)silyl-substituted hydrocarbyl; each R² is independently selected from the group consisting of hydrocarbyl, O-, N-, S-, Se-, halogen-, and tri(hydrocarbyl)silyl-substituted hydrocarbyl, and O-, N-, S-, and Se-based functional groups; and each R⁴ is independently selected from the group consisting of hydrogen, O-, N-, S-, Se-, halogen- and tri(hydrocarbyl)silyl-substituted hydrocarbyl, and O-, N-, S-, and Se-based functional groups.

5. The ink of claim 1, wherein the nitrogen-, oxygen-, carbon-, sulfur-, and selenium-based organic ligands are selected from the group consisting of: amidos; alkoxides; acetylacetonates; carboxylates; hydrocarbyls; O-, N-, S-, Se-, halogen-, and tri(hydrocarbyl)silyl-substituted hydrocarbyls; thio- and selenolates; thiO-, selenO-, and dithiocarboxylates; dithiO-, diselenO-, and thioselenocarbamates; and dithioxanthogenates.

6. The ink of claim 1, wherein the vehicle comprises a solvent and the boiling point of the solvent is greater than about 100° C. at atmospheric pressure.

7. A coated substrate comprising:
a) a substrate; and
b) at least one layer disposed on the substrate comprising:
1) a molecular precursor to CZTS/Se, comprising:
i) a copper source selected from the group consisting of copper complexes of N-, O-, C-, S-, and Se-based organic ligands, copper sulfides, copper selenides, and mixtures thereof;
ii) a tin source selected from the group consisting of tin complexes of N-, O-, C-, S-, and Se-based organic ligands, tin hydrides, tin sulfides, tin selenides, and mixtures thereof;
iii) a zinc source selected from the group consisting of zinc complexes of N-, O-, C-, S-, and Se-based organic ligands, zinc sulfides, zinc selenides, and mixtures thereof; and
iv) optionally a vehicle, comprising a liquid chalcogen compound, a liquid tin source, a solvent, or a mixture thereof; and
2) a plurality of particles selected from the group consisting of: CZTS/Se particles; elemental Cu-, elemental Zn- or elemental Sn-containing particles; binary or ternary Cu-, Zn- or Sn-containing chalcogenide particles; and mixtures thereof.

8. A process comprising disposing an ink onto a substrate to form a coated substrate, wherein the ink comprises:
a) a molecular precursor to CZTS/Se, comprising:
i) a copper source selected from the group consisting of copper complexes of N-, O-, C-, S-, and Se-based organic ligands, copper sulfides, copper selenides, and mixtures thereof;
ii) a tin source selected from the group consisting of tin complexes of N-, O-, C-, S-, and Se-based organic ligands, tin hydrides, tin sulfides, tin selenides, and mixtures thereof;
iii) a zinc source selected from the group consisting of zinc complexes of N-, O-, C-, S-, and Se-based organic ligands, zinc sulfides, zinc selenides, and mixtures thereof; and
iv) a vehicle, comprising a liquid chalcogen compound, a liquid tin source, a solvent, or a mixture thereof; and
b) a plurality of particles selected from the group consisting of: CZTS/Se particles; elemental Cu-, elemental Zn- or elemental Sn-containing particles; binary or ternary Cu-, Zn- or Sn-containing chalcogenide particles; and mixtures thereof.

9. The process of claim 8, further comprising a drying step at about 80° C. to about 350° C.

10. The process of claim 8, further comprising an annealing step at about 350° C. to about 800° C., and wherein the annealing comprises thermal processing, rapid thermal processing, rapid thermal annealing, pulsed thermal processing, laser beam exposure, heating via IR lamps, electron beam exposure, pulsed electron beam processing, heating via microwave irradiation, or combinations thereof.

11. The process of claim 10, wherein the annealing is carried out under an atmosphere comprising an inert gas and a chalcogen source.

12. The process of claim 10, further comprising disposing one or more layers selected from the group consisting of buffer layers, top contact layers, electrode pads, and antireflective layers onto the annealed CZTS-Se film.

13. A film comprising:
a) an inorganic matrix; and
b) CZTS/Se microparticles characterized by an average longest dimension of 0.5-200 microns, wherein the microparticles are embedded in the inorganic matrix.

14. A photovoltaic cell comprising the film of claim 13.
